(19) United States
(12) Patent Application Publication
(10) Pub. No.: US 2026/0096086 A1
(43) Pub. Date: Apr. 2, 2026

(54) ASYMMETRIC MEMORY STRUCTURES AND METHODS OF FABRICATING THE SAME

(71) Applicant: Taiwan Semiconductor Manufacturing Company, Ltd., Hsinchu (TW)

(72) Inventors: Yu-Chien Chiu, Hsinchu City (TW); Wen-Ling Lu, Hsinchu City (TW); Ya-Yun Cheng, Hsinchu City (TW); Yi-Ching Liu, Hsinchu City (TW); Yih Wang, Hsinchu City (TW); Zhiqiang Wu, Hsinchu City (TW); Chieh Lee, Hsinchu City (TW)

(73) Assignee: Taiwan Semiconductor Manufacturing Company, Ltd., Hsinchu (TW)

(21) Appl. No.: 18/999,445

(22) Filed: Dec. 23, 2024

Related U.S. Application Data
(60) Provisional application No. 63/702,236, filed on Oct. 2, 2024.

(51) Int. Cl. H10B 12/00

(52) U.S. Cl. CPC H10B 12/315; H10B 12/05

(57) ABSTRACT

A memory device includes a channel layer. The memory device includes a gate structure on a first side of the channel layer, where the gate structure has a top surface facing the channel layer. The memory device includes a drain structure on a second side of the channel layer opposite to the first side, where the drain structure has a first bottom surface in contact with the channel layer. The first bottom surface underlaps the top surface of the gate structure across a first lateral direction. The memory device includes a source structure on the second side of the channel layer and adjacent to the drain structure along the first lateral direction, where the source structure has a second bottom surface facing the channel layer. The second bottom surface overlaps the top surface of the gate structure across the first lateral direction.

### CROSS-REFERENCE TO RELATED APPLICATIONS

The present application claims priority to U.S. Provisional Application No. 63/702,236, filed Oct. 2, 2024, the entire disclosure of which is incorporated herein by reference for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. With respect to memory devices and structures, continued improvement in alternating current (AC) performance of the devices is desirable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional perspective view of an embodiment of a memory device, in accordance with some embodiments.

FIG. 2 illustrates a cross-sectional view taken along line AA′ of the memory device of FIG. 1, in accordance with some embodiments.

FIG. 3 illustrates a cross-sectional view taken along line BB′ of the memory device of FIG. 1, in accordance with some embodiments.

FIGS. 4 and 10 each illustrate a three-dimensional perspective view of a portion of the memory device shown as DETAIL A of FIG. 1, in accordance with some embodiments.

FIG. 5 illustrates a circuit diagram of the memory device of FIG. 1, in accordance with some embodiments.

FIGS. 6 and 8 each illustrate a cross-sectional view of a portion of the memory device shown as DETAIL B of FIG. 2, in accordance with some embodiments.

FIGS. 7A and 7B each illustrate a planar top view across an interface of a portion of the memory device as shown in FIG. 6, in accordance with some embodiments.

FIG. 9 illustrates a planar top view across a portion of the memory device as shown in FIG. 8, in accordance with some embodiments.

FIGS. 11A and 11B each illustrate a planar top view across an interface of a portion of the memory device as shown in FIG. 10, in accordance with some embodiments.

FIG. 12 illustrates a three-dimensional perspective view of an embodiment of a memory device, in accordance with some embodiments.

FIG. 13 illustrates a cross-sectional view taken along line CC′ of the memory device of FIG. 12, in accordance with some embodiments.

FIGS. 14 and 16 each illustrate a cross-sectional view of a portion of the memory device shown as DETAIL C of FIG. 13, in accordance with some embodiments.

FIGS. 15A, 15B, and 15C each illustrate a planar top view across a portion of the memory device as shown in FIG. 14, in accordance with some embodiments.

FIG. 17 illustrates a three-dimensional perspective view of a portion of the memory device shown as DETAIL D of FIG. 16, in accordance with some embodiments.

FIGS. 18 and 20 each illustrate a three-dimensional perspective view of an embodiment of a memory device, in accordance with some embodiments.

FIGS. 19A, 19B, and 19C each illustrate a cross-sectional view taken along line DD′ of the memory device of FIG. 18, in accordance with some embodiments.

FIGS. 21A and 21B each illustrate a cross-sectional view taken along line EE′ of the memory device of FIG. 20, in accordance with some embodiments.

FIG. 22 illustrates a three-dimensional perspective view of an embodiment of a memory device, in accordance with some embodiments.

FIG. 23 illustrates a cross-sectional view taken along line FF′ of the memory device of FIG. 22, in accordance with some embodiments.

FIG. 24 is an example flowchart of a method for fabricating an embodiment of a memory device, in accordance with some embodiments.

FIGS. 25, 26, 27, 28, 29, 30, 31, and 32 illustrate perspective views of the memory device during various fabrication stages of the method as shown in FIG. 24, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally directed to back-end-of-line (BEOL) memory devices and methods of fabricating the same. Specifically, the present disclosure is directed to BEOL memory devices having asymmetric dimensions in drain and source structures and underlapping configuration between the drain structure and gate structure. While existing BEOL memory devices have been generally adequate, they have not been entirely satisfactory in all aspects. For example, it remains a challenge for tuning gate-to-drain capacitance of each memory cell to achieve reduced loading on local bit line structures and improved charge sharing ratio.

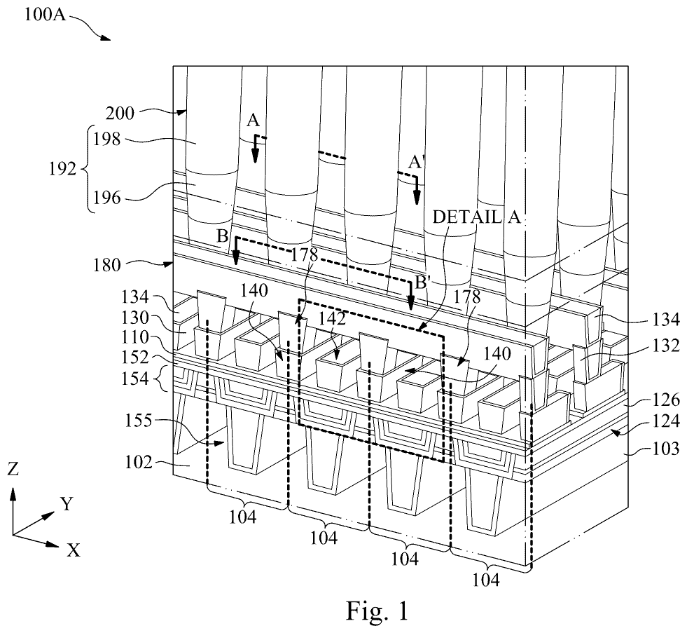

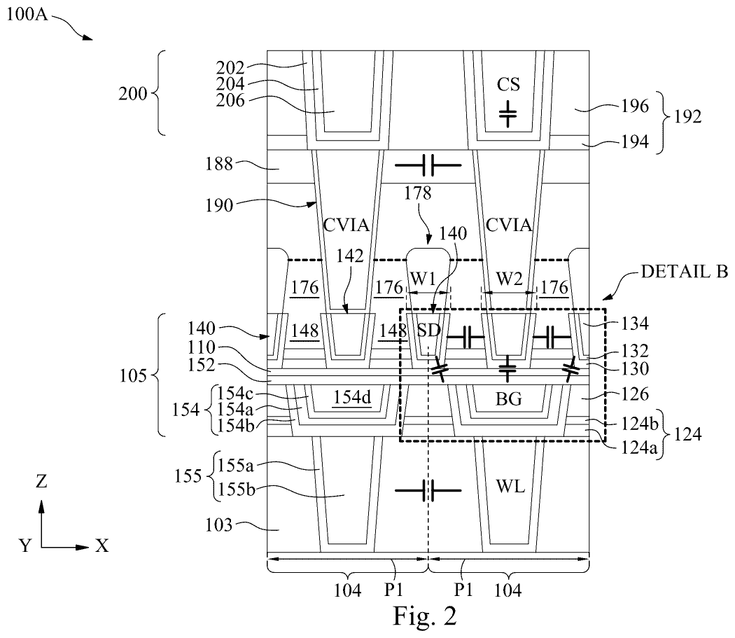

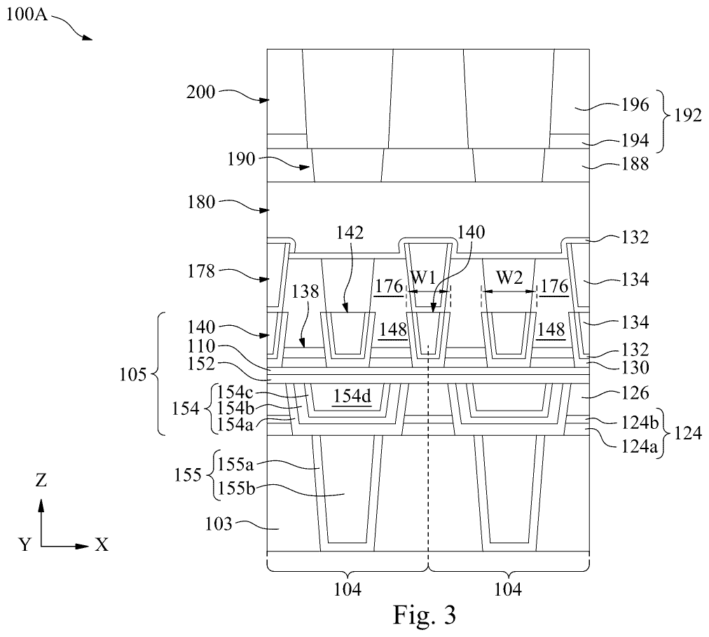

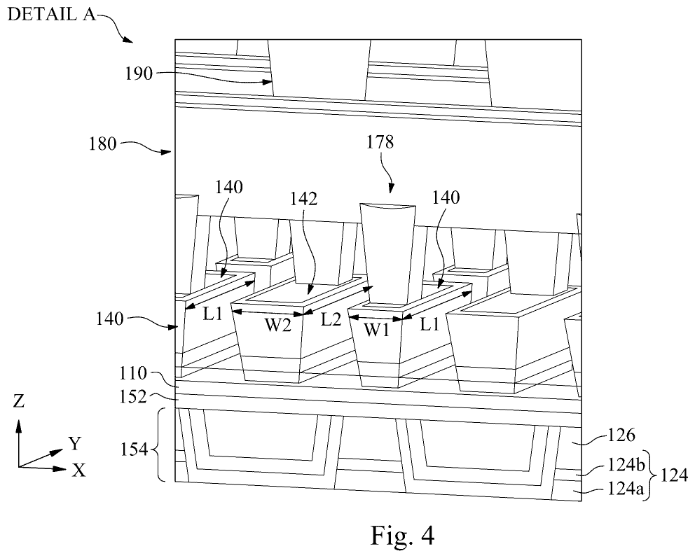

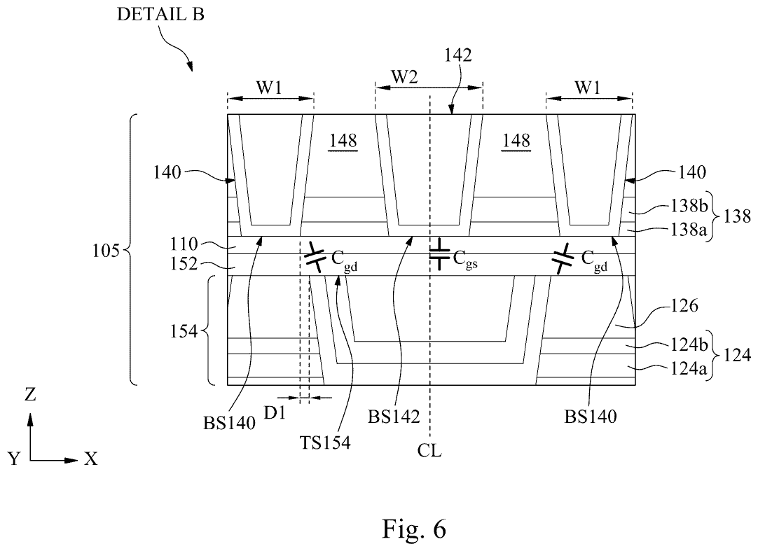

According to various embodiments of the present disclosure, FIG. 1 illustrates a three-dimensional perspective view of a memory device 100A; FIG. 2 illustrates a cross-sectional view of the memory device 100A taken along line AA′ as shown in FIG. 1; FIG. 3 illustrates a cross-sectional view of the memory device 100A taken along line BB′ as shown in FIG. 1; FIG. 4 illustrates a three-dimensional perspective view of a portion of the memory device 100A shown as DETAIL A in FIG. 1; and FIG. 6 illustrates a cross-sectional view of a portion of the memory device 100A shown as DETAIL B in FIG. 2. The memory device 100A includes a plurality of memory cells 104 arranged as a memory array (e.g., four memory cells 104 are shown in the example of FIG. 1) that extends along both a X direction (alternatively referred to as a first lateral direction) and the Y direction (alternatively referred to as a second lateral direction). It should be understood that the various perspective and cross-sectional views of the memory device 100A described herein are simplified, and thus, it should be understood that any other features/components can also be included in figures pertaining to the memory device 100A, while remaining within the scope of the present disclosure.

In an overview, each of the memory cells 104 is disposed over a frontside of a base structure 102, which includes a semiconductor substrate, and includes at least a transistor 105 electrically coupled to a capacitor 200. In various embodiments, the transistor 105 includes a channel layer 110 having a backside facing the base structure 102 and a frontside opposite to the backside, a pair of drain structure 140 and source structure 142 disposed on the frontside of the channel layer 110 and spaced apart along the X direction, a gate dielectric layer 152 disposed on the backside of the channel layer 110, and a gate structure 154 (also referred to as a gate electrode 154) disposed on the gate dielectric layer 152. As used herein, the “backside” of the channel layer 110 is proximate to the base structure 102 and the “frontside” of the channel layer 110 is distal to the base structure 102. In this regard, the gate structure 154 is also referred to as a back-side gate structure 154. The memory cell 104 further includes a source line via (SVIA) 190 configured to electrically couple the source structure 142 to the capacitor 200. For illustrative purposes only, a dimension P1, also referred to as a cell pitch P1, of the memory cell 104 extending along the X direction is defined between centerlines of two adjacent drain structures 140.

The memory device 100A includes a plurality of word line (WL) structures 155 each electrically coupled to, such as by direct contact, the gate structure 154 of a given memory cell 104. Each WL structure 155 is disposed between the memory cell 104 and the base structure 102 along a Z direction (alternatively referred to as a vertical direction). In various embodiments, the WL structure 155 is vertically aligned with the corresponding gate structure 154 along the Z direction. The memory device 100 further includes a bit line (BL) structure 180 electrically coupled to each drain structure 140 of the memory cell 104 through a bit line via (BVIA) structure 178.

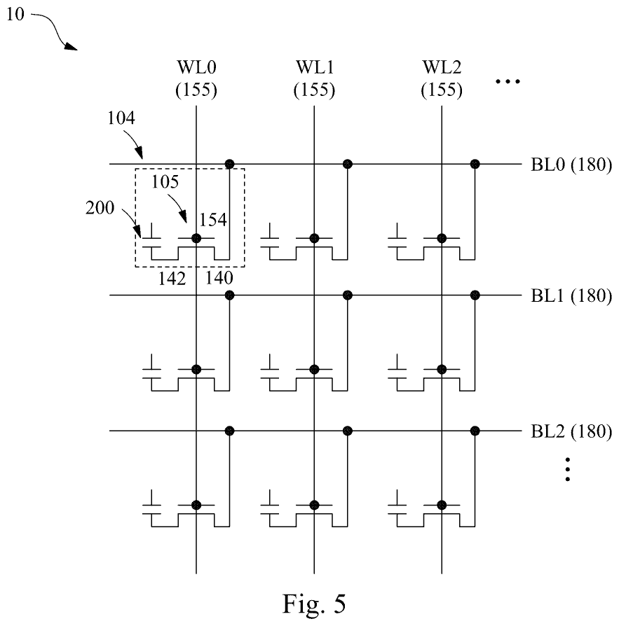

FIG. 5 illustrates a schematic circuit diagram 10 representing an embodiment of the memory device 100A. In this regard, the gate structure 154 of each memory cell 104 is electrically coupled to a corresponding WL structure 155 (e.g., WL0, WL1, WL2, etc.), the drain structure 140 of each memory cell 104 is electrically coupled to a corresponding BL structure 180 (e.g., BL0, BL1, BL2, etc.), and the source structure 142 of each memory cell 104 is electrically coupled to a corresponding capacitor 200 of the same memory cell 104.

Still referring to FIGS. 1-4, the base structure 102 includes the semiconductor substrate (not depicted separately) having an elementary semiconductor material such as silicon, germanium, diamond, other elementary semiconductor material, a compound semiconductor material such as silicon germanium, silicon carbide, gallium arsenic, indium arsenide, indium phosphide, silicon germanium carbide, gallium arsenic phosphide, gallium indium phosphide, other compound semiconductor materials, or combinations thereof. A plurality of active/passive device features that collectively or respectively function as a logic circuit (e.g., transistors, capacitors, resistors, etc.) may be formed in or over a frontside of a major surface of the semiconductor substrate.

The base structure 102 may further include a plurality of interconnect structures (e.g., conductive lines, vias, etc.) embedded in one or more dielectric layers (e.g., intermetal (IMD) layers, etch-stop layers (ESLs), etc.) and configured to electrically couple the device features formed in or over the semiconductor substrate to the memory cells 104 depicted in FIGS. 1-4. In some examples, each dielectric layer embedded with its corresponding interconnect structures may be referred to as a metallization layer. Metallization layers sequentially formed over the semiconductor substrate may be denoted as M0, M1, M2, etc., in such an order. The device features formed in or over the major surface of the semiconductor substrate are typically referred to as a part of front-end-of-line (FEOL) networking/processing, and those interconnect structures formed in the dielectric layers are typically referred to as a part of middle-end-of-line (MEOL) and a BEOL networking/processing. In various embodiments, components of the memory device 100A as depicted herein are formed within the BEOL networking of the memory device 100A.

In some embodiments, the memory device 100A includes a dielectric layer 103 in which the WL structures 155 are embedded or surrounded, where the dielectric layer 103 and the WL structures 155 together comprise a M5 metallization layer, or the fifth metallization layer, over the semiconductor substrate. The dielectric layer 103 is configured to insulate adjacent WL structures 155 from one another and may include any suitable dielectric material, such as silicon oxide (SiO₂), silicon nitride (Si₃N₄), silicon oxynitride (SiON), dielectric material(s) with low dielectric constant (low-k), such as SiCOH, SiOCN, and/or SiOC, other suitable materials, or combinations thereof. As used herein, a low-k dielectric material refers to a dielectric material with a dielectric constant lower than about 3.9.

In some embodiments, still referring to FIGS. 1-4, the WL structures 155 each extend (in a lengthwise direction) along the Y direction and are spaced apart along the X direction over the base structure 102. Each WL structure 155 includes a fill layer 155b disposed over or surrounded by a barrier layer 155a. The barrier layer 155a may include any suitable conductive material, such as titanium nitride (TiN), tantalum nitride (TaN), tungsten nitride (WN), other suitable materials, or combinations thereof. The fill layer 155b may include any suitable conductive material, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), TaN, TiN, TiAl, polycrystalline silicon (polysilicon), other suitable conductive materials, or combinations thereof.

The memory device 100A further includes a dielectric layer 126 in which the gate structures 154 are embedded. The dielectric layer 126 may be similar to or the same as the dielectric layer 103 in structure and composition. The gate structures 154 each extend (in a lengthwise direction) parallel to the corresponding WL structure 155 along the Y direction and are spaced apart along the X direction over the base structure 102.

In various embodiments, the gate structure 154 includes multiple material layers 154a, 154b, 154c, and 154d sequentially formed over the dielectric layer 126. The material layers 154a, 154b, and 154d may each include a conductive material, such as TiN, TaN, WN, Cu, Co, Ru, Mo, Cr, W, Mn, Rh, Ir, Ni, Pd, Pt, Ag, Au, Al, polysilicon, other suitable conductive materials, or combinations thereof. In some embodiments, the material layers 154a, 154b, and 154d may differ in composition. In some embodiments, the material layer 154c includes a hydrogen-absorption material configured to scavenge and remove any hydrogen atoms released by the gate structure 154, thereby protecting the nearby channel layer 110 from inadvertent chemical degradation. In this regard, the material layer 154c may include a metal-like, conductive oxide, such as indium oxide (In₂O₃), aluminum oxide (Al₂O₃), other suitable materials, or combinations thereof. In some embodiments, the gate structure 154 includes at least one of the material layers 154a-154d. In some embodiments, one or more of the material layer 154a-154d are omitted from the gate structure 154.

The memory device 100A may further include an absorption structure 124 disposed between two adjacent gate structures 154 along the X direction and extending lengthwise along the Y direction. The absorption structure 124 is disposed between the dielectric layer 126 and the dielectric layer 103 along the Z direction. In some embodiments, the absorption structure 124 includes multiple material layers, such as a dielectric layer 124a and an absorption layer 124b, also referred to as a hydrogen absorption layer 124b, over the dielectric layer 124a. As provided herein, the dielectric layer 124a is in direct contact with the dielectric layer 103 and may be similar to or the same as the dielectric layer 103 in composition. The absorption layer 124b, on the other hand, is disposed between the dielectric layer 124a and the dielectric layer 126 and may include a hydrogen-absorption material similar to the composition of the material layer 154c described above. For example, the absorption layer 124b may be configured to protect the channel layer 110 from reacting with hydrogen atoms released from the surrounding components. In this regard, the absorption layer 124b may be similar to or the same as the material layer 154c in composition. In the depicted embodiments, each sidewall of the gate structure 154 directly contacts the absorption structure 124 (i.e., each of its material layers) and the dielectric layer 126. In this regard, the absorption structure 124 and the dielectric layer 126 are interposed between adjacent gate structures 154 along the X direction.

Still referring to FIGS. 1-4, the gate dielectric layer 152 may include any suitable dielectric material, such as silicon oxide (SiO₂), hafnium oxide (HfO₂), aluminum oxide (Al₂O₃), silicon oxynitride (SiON), lanthanum oxide (La₂O₃), zirconium oxide (ZrO₂), titanium oxide (TiO₂), manganese oxide (MgO) tantalum oxide silicon (Ta₂O₅), other suitable dielectric materials, or combinations thereof. In some embodiments, the gate dielectric layer 152 includes a high-k dielectric material (e.g., HfO₂, Al₂O₃, ZrO₂, TiO₂, MgO, Ta₂O₅, etc.). As used herein, a high-k dielectric material refers to a dielectric material with a dielectric constant that is generally greater than about 3.9. In the present embodiments, the gate dielectric layer 152 extends continuously along both the X direction and the Y direction across adjacent memory cells 104. In other words, portions of the gate dielectric layer 152 are disposed over both the gate structure 154 and the dielectric layer 126 adjacent thereto.

As depicted herein, the channel layer 110 of the memory device 100A extends lengthwise along the X direction and overlaying the gate dielectric layer 152 to define a channel region of each transistor 105 in the memory cell 104. In other words, a portion of the channel layer 110 extends a distance equivalent to the cell pitch P1 within each memory cell 104. In some embodiments, portions of the channel layer 110 are disposed the dielectric layer 126 between adjacent gate structures 154.

The channel layer 110 generally includes one or more metal oxide-based semiconductor material. In this regard, the channel layer 110 may be alternatively referred to as the semiconductor layer 110. In some embodiments, the channel layer 110 includes an N-type channel material such as indium gallium zinc oxide (IGZO), zinc oxide (ZnO), In₂O₃, tin (IV) oxide (SnO₂), other suitable N-type channel materials, or combinations thereof. In some embodiments, the channel layer 110 includes a P-type channel layer that includes nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), tin (II) oxide (SnO), other suitable P-type channel materials, or combinations thereof. Other metal oxide materials, such as indium tungsten oxide (IWO), indium zinc oxide (IZO), indium tungsten zin oxide (IWZO), indium tin zinc oxide (ITZO), indium tin oxide (ITO), and/or indium gallium oxide (IGO) may also be included in the channel layer 110. In some embodiments, the channel layer 110 including a N-type channel material renders the transistor 105 an N-type transistor, and the channel layer 110 including a P-type channel material renders the transistor 105 a P-type transistor. In some embodiments, the concentration of oxygen in the channel layer 110 may be adjusted to achieve specific design requirements. In the present embodiments, the channel layer 110 is free, or substantially free, of any silicon-containing semiconductor material.

Referring to FIGS. 2 and 3 and further to FIG. 6, the memory device 100A includes an absorption structure 138 disposed over the channel layer 110 and a dielectric layer 148 disposed over the absorption structure 138. In some embodiments, the absorption structure 138 is similar to or the same as the absorption structure 124 in structure and composition as described above, and the dielectric layer 148 is similar to or the same as the dielectric layer 103 in composition as described above. For example, the absorption structure 138 may include a dielectric layer 138a and an absorption layer 138b, where the dielectric layer 138a is in direct contact with a frontside of the channel layer 110 and the absorption layer 138b is disposed between the dielectric layer 138a and the dielectric layer 148.

Still referring to FIGS. 1-4, the plurality of the drain structures 140 and the source structures 142 are disposed over the channel layer 110 and arranged in an alternating pattern along the X direction, where each memory cell 104 includes a pair of the drain structure 140 and the source structure 142 adjacent thereto. The drain structures 140 and the source structures 142 are embedded in or surrounded by the dielectric layer 148 and the absorption structure 138, which provide electrical isolation therebetween. In this regard, a sidewall of each of the drain structures 140 and the source structures 142 directly contacts the absorption structure 138 (i.e., each material layers thereof) and the dielectric layer 148.

In the depicted embodiments, the gate structure 154 of each memory cell 104 extends between two adjacent drain structures 140 along the X direction, fully engaging a bottom surface BS142 of the source structure 142 disposed therebetween. In other words, two adjacent drain structures 140 are respectively disposed on each side of the gate structure 154. In the present disclosure, the source structure 142 may be alternatively referred to as a source metal electrode 142 and the drain structure 140 may be alternative referred to as a drain metal electrode 140.

In the present embodiments, the drain structure 140 and the source structure 142 include the same structure and composition and may include multiple material layers. For example, still referring to FIGS. 1-3, each of the drain structure 140 and the source structure 142 includes an absorption layer 130, a metal layer 132 disposed over the absorption layer 130, and a metal layer 134 disposed over the metal layer 132.

In some embodiments, the absorption layer 130 has a composition similar to or the same as that of the material layer 154c. For example, the absorption layer 130 may include a metal-like, conductive oxide, such as indium oxide (In₂O₃), aluminum oxide (Al₂O₃), other suitable materials, or combinations thereof. In some embodiments, the absorption layer 130 is omitted from the drain structure 140 and the source structure 142.

In some embodiments, the metal layer 132 and the metal layer 134 each include a conductive material, such as W, Al, polysilicon, Ru, Co, Cu, Mo, Nb, TaN, TiN, other suitable conductive materials, or combinations thereof. In some embodiments, the metal layer 132 and the metal layer 134 differ in composition. In some embodiments, the metal layer 134 includes a conductive material having a lower contact resistance that that of the metal layer 132. For example, in the depicted embodiments, the metal layer 132 includes TiN and the metal layer 134 includes W. In some instances, the metal layer 132 may be considered a barrier layer, which may be similar to or the same as the barrier layer 155a in composition, and the metal layer 134 may be considered a fill layer, which may be similar to or the same as the fill layer 155b in composition.

Still referring to FIGS. 1-4, the BVIA structures 178 and the BL structures 180 are embedded in or surrounded by a dielectric layer 176, while the SVIA structures 190 are embedded in or surrounded by a dielectric layer 188. The dielectric layer 176 is disposed over the dielectric layer 148 and may be similar to or the same as the dielectric layer 103 in composition. The dielectric layer 188 is disposed over the dielectric layer 176 and may also be similar to or the same as the dielectric layer 103 in composition.

The BL structure 180 extends lengthwise along the X direction and is electrically coupled to each of the drain structures 140 by a corresponding BVIA structure 178 that extends vertically along the Z direction. In some embodiments, a bottom surface of the BVIA structure 178 directly contacts at least a portion of a top surface of the drain structure 140. For example, the bottom surface of the BVIA structure 178 directly contacts the metal layer 132 and the metal layer 134 of the drain structure 140. In some embodiments, a top surface of the BVIA structure 178 extends into or is embedded in the BL structure 180.

Each of the SVIA structures 190 extends vertically along the Z direction and electrically couples each of the source structures 142 to a corresponding capacitor 200. In some embodiments, a bottom surface of the SVIA structure 190 directly contacts at least a portion of a top surface of the source structure 142. For example, the bottom surface of the SVIA structure 190 directly contacts the metal layer 132 and the metal layer 134 of the source structure 142. Furthermore, a top surface of the SVIA structure 190 directly contacts a bottom surface of the capacitor 200.

The BVIA structure 178, the BL structure 180, and the SVIA structure 190 may include similar or the same compositions. In some embodiments, the BVIA structure 178, the BL structure 180, and the SVIA structure 190 each include multiple material layers. For example, the BVIA structure 178, the BL structure 180, and the SVIA structure 190 may each include the metal layer 132 over their corresponding dielectric layers (e.g., the dielectric layer 176 or the dielectric layer 188) and the metal layer 134 over the metal layer 132.

Still referring to FIGS. 1-4, the capacitor 200 is embedded in or surrounded by a dielectric structure 192, which includes an absorption layer 194, a dielectric layer 196 over the absorption layer 194, and a dielectric layer 198 over the dielectric layer 196. In some embodiments, the absorption layer 194 is similar to or the same as the absorption layer 124b in composition, and the dielectric layers 196 and 198 differ in composition. The dielectric layers 196 and 198 may each include a suitable dielectric material, such as SiO₂, Si₃N₄, SiON, Al₂O₃, a low-k dielectric material (e.g., SiCOH, SiOCN, SiOC, etc.), other suitable materials, or combinations thereof. The dielectric structure 192 may include less, more, or different layers as those provided herein.

In various embodiments, the capacitor 200 generally has a metal-insulator-metal (MIM) structure having an insulating or dielectric layer sandwiched between two conductive layers or plates. The memory cell 104, which includes the transistor 105 electrically coupled to the capacitor 200, may be generally described to have a 1-transistor-1-capacitor, or 1T1C, structure. Depending upon the types of materials employed in the capacitor 200, the memory cell 104 may be configured as adynamic random-access memory (DRAM) cell, a magnetoresistive random-access memory (MRAM) cell (also referred to as a magnetic tunnel junction, or MTJ, cell), a resistive random-access memory (ReRAM) cell, a ferroelectric random-access memory (FeRAM) cell, the like, or other suitable types of memory cells that have been, are being, or will be developed. In the depicted embodiments, the memory cell 104 may be configured as a DRAM cell.

In the depicted embodiments, for example, each capacitor 200 includes a bottom plate 202 (also referred to as bottom metal layer 202), a capacitor dielectric layer 204 over the bottom plate 202, and a top plate 206 (also referred to as top metal layer 206) over the capacitor dielectric layer 204. Each of the bottom plate 202 and the top plate 204 may include a conductive material, such as iron (Fe), W, Cu, Co, Ru, Al, Ti, Ta, Au, Ag, Pt, other suitable conductive materials, or combinations (or alloys) thereof, and the capacitor dielectric layer 204 may include a suitable dielectric material, such as a high-k dielectric material (e.g., HfO₂, Al₂O₃, ZrO₂, TiO₂, MgO, Ta₂O₅, etc.), other suitable dielectric materials, or combinations thereof.

For memory devices having a 1T1C structure, such as that of the memory device 100A, it is generally desirable to improve the device's AC performance, which may include, for example, reducing loading on local BL structures, enhancing charge sharing ratio, and improving memory latency time, which affects component reading speed. In many instances, achieving these design goals has been met with many challenges. In one such challenge, transistor with large capacitance (i.e., gate-to-drain capacitance, or C_{gd}) between a drain structure and a gate structure of the transistor may lead to longer latency time and increase an overall capacitance C_{selector} of the transistor (or selector) 105, leading to larger loading on local BL structures (i.e., large BL capacitance, or C_{BL}). Various sources of capacitance are indicated in FIG. 2, for example. The larger loading on the local BL structures may subsequently reduce charge sharing ratio of the memory device, resulting in limited flexibility in memory circuit design. While existing memory circuit designs have addressed such challenge to various degrees, they have not been entirely satisfactory in all aspects.

In existing 1T1C memory devices, source and drain structures of a given memory cell are generally configured to have the same or substantially the same dimensions along each of the X direction and the Y direction (i.e., the same or substantially the same footprint), rendering the drain and source structures to be symmetrically positioned about a gate structure of the memory cell. In addition, each pair of adjacent drain structures are placed relative to each gate structure in an overlapping manner, where an edge of a bottom surface of the drain structure and a nearby edge of a top surface of the gate structure overlap along the X direction. In other words, an overlapping area between the drain structure and the gate structure is positive (i.e., greater than zero), where the overlapping area extends along both the X direction and the Y direction. These configurations generally provide less capability and/or flexibility for designing and fabricating memory devices with reduced the C_{gd}, reduced BL loading, and/or improved charge sharing ratio.

The present disclosure provides various configurations of the transistor component of 1T1C memory devices with reduction in the C_{gd}, reduction in BL loading, and improvement in charge sharing ratio. Furthermore, these configurations may be fine-tuned to achieve enhancement in one or both of the AC performance and direct current (DC) performance (e.g., write back current I_{wb}) of the memory devices. In some embodiments of the present disclosure, tuning the configurations of the transistor's components(s) to reduce the C_{gd}, and the BL loading by extension, includes adjusting an area of the drain structure facing the gate structure, a separation distance between the drain structure and the gate structure, or both. In some embodiments, adjusting one or both of the area of the drain structure facing the gate structure and the separation distance between the drain structure and the gate structure effectively changes an overlapping area between the drain structure and the gate structure.

Specifically, in some examples, adjusting the area of the drain structure facing the gate structure may include adjusting a dimension of the drain structure along the X direction relative to the source structure. Alternatively or additionally, adjusting the area of the drain structure facing the gate structure may include adjusting a dimension of the drain structure along Y direction relative to the source structure. In this regard, adjusting one or both dimensions of the drain structure relative to the source structure reduces the overlapping area between the drain structure and the gate structure and results in an asymmetric configuration in the transistor component. In some examples, adjusting the separation distance between the drain structure and the gate structure includes reducing an overlapping distance between the drain structure and the gate structure, and the overlapping area therebetween by extension, rendering the drain structure and the gate structure to underlap or non-overlap one another.

“Underlapping” or “non-overlapping” between two surfaces, as described herein, may refer to the two surfaces being separated by a distance along a lateral direction, or alternatively, having edges vertically aligned or coincide with one another. In this regard, an underlapping or non-overlapping configuration corresponds to a separation distance that is greater than or equal to zero, while an overlapping configuration corresponds to a separation distance that is less than zero. In various embodiments, underlapping between the gate structure and the drain structure improves the AC performance of the memory device by reducing the C_{gd}. In addition or alternative to implementing underlapping between the drain structure and the gate structure, by reducing the dimension of the drain structure relative to that of the source structure along the X direction, resistance of the source structure is lowered and metrics such as write-back current I_{wb} are enhanced, leading to improved DC performance of the memory device.

Various non-limiting example configurations demonstrating these design concepts are described in detail below.

In some embodiments, referring to FIGS. 1-4, 6, 7A, 7B, the drain structures 140 are each configured with a first width W1 along the X direction and a first length L1 along the Y direction, and the source structures 142 are each configured with a second width W2 along the X direction and a second length L2 along the Y direction, where the first width W1 is less than the second width W2 and the first length L1 is the same or substantially the same as the second length L2. As such, the drain structure 140 and the source structure 142 to have asymmetric dimensions along the X direction. Furthermore, a first area A1 of a bottom surface BS140 of the drain structure 140 facing the channel layer 110 is less than a second area A2 of a bottom surface BS142 of the source structure 142, where each of the first area A1 and the second area A2 extends along the X direction and the Y direction. In some instances, the drain structure 140 having an elongated dimension similar to that of the source structure 142 may be referred to as a slot-type drain structure 140.

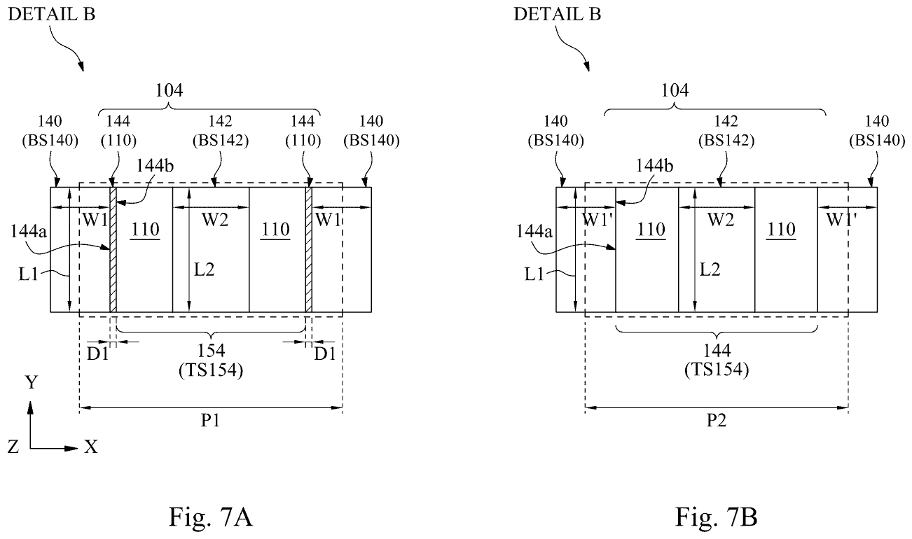

FIG. 7A illustrates an example top view of the transistor 105 taken along an interface between the drain structure 140 (and the source structure 142) and the channel layer 110 with the gate structure 154 disposed below the plane of view. The first area A1 is then defined by a product of the first width W1 and the first length L1, and the second area A2 is similarly defined by a product of the second width W2 and the second length L2, which is larger than the first area A1. Accordingly, in contrast to existing device designs in which the first area A1 and the second area A2 are configured to be the same (i.e., the drain structure and the source structure having symmetric dimensions), reducing the first area A1 relative to the second area A2 effectively reduces the C_{gd} between the drain structure 140 and the gate structure 154, thereby reducing at least the BL loading of the memory device 100A (e.g., reducing the C_{BL} of the BL structure 180).

In some embodiments, still referring to FIG. 7A, the bottom surface BS140 of the drain structure 140 is separated or laterally offset from a top surface TS154 of the gate structure 154 by an underlapping region 144 (defined in the channel layer 110) having a first distance D1 and symmetrically disposed about the source structure 142 along the X direction. In this regard, an edge 144a of the bottom surface BS140 is separated from an edge 144b of the top surface TS154 by the first distance D1 such that the two surfaces do not overlap but underlap, and an underlapping area B1 of the underlapping region 144 may be defined by a product of the first distance D1 and the first length L1, for example. The underlapping of the bottom surface BS140 and the top surface TS154 effectively increases a separation distance between the drain structure 140 and the gate structure 154, which reduces the C_{gd} of the memory cell 104.

In some embodiments, the first distance D1, also referred to as an underlapping distance D1, is greater than 0 and less than about 4% of the cell pitch P1 defined herein. If the first distance D1 is too large, e.g., greater than about 4% of the cell pitch P1, gate control of the drain structure 140 may be compromised, thereby degrading the performance of the memory device 100A. If, on the other hand, the first distance D1 is too small, e.g., less than 0, the effect of reducing C_{gd} may not be significant enough to result in a decreased loading on the BL structure 180 and an improved charge sharing ratio by extension.

In some embodiments, referring to FIG. 7B, the edge 144a of the bottom surface BS140 is vertically aligned with the edge 144b of the top surface TS154 such that the two surfaces do not overlap but underlap. In other words, the edge 144a and the edge 144b coincide with one another. In the depicted embodiment, the vertical alignment between the drain structure 140 and the gate structure 154 is symmetrical about the source structure 142 along the X direction. Different from the embodiment depicted in FIG. 7A, the vertical alignment of the bottom surface BS140 and the top surface TS154 indicates an underlapping area that is substantially zero.

In some non-limiting examples, by configuring the drain structure 140 and the source structure 142 to have asymmetric dimensions and by introducing the underlapping region 144 (defined by the first distance D1), the BL loading may be reduced by about 10% to about 18%. Additionally, referring to both FIGS. 7A and 7B, the reduction of the first width W1 relative to the second width W2 may be fine-tuned to reduce the overall cell pitch P1 of the memory cell 104, thereby improving density of the memory cells 104 in the memory device 100A. In this regard, the first width W1 may be adjusted such that the cell pitch P1 depicted in FIG. 7A may be reduced in comparison to that of a memory cell having symmetric dimensions between the drain structure 140 and the source structure 142. In some examples, by vertically aligning the edge 144a and the edge 144b, a cell pitch P2 that is less than the cell pitch P1 by a distance equivalent to twice of the first distance D1 may be obtained.

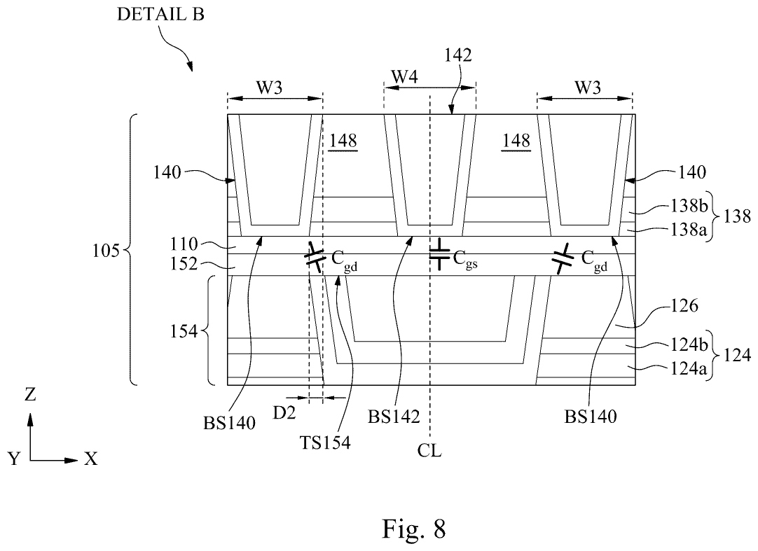

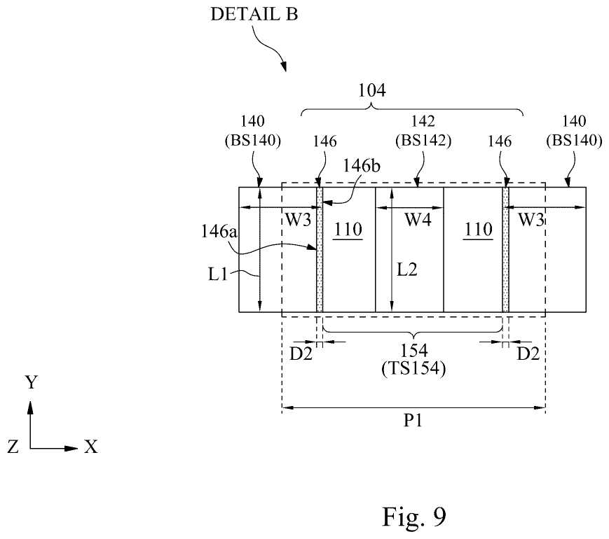

FIGS. 8 and 9 collectively depict an embodiment of the memory device 100A that is similar to that depicted in FIGS. 6-7B, where FIG. 8 illustrates a cross-sectional view of a portion of the memory device 100A shown as DETAIL B in FIG. 2 and FIG. 9 illustrates an example top view of the transistor 105 taken along an interface between the drain structure 140 and the channel layer 110. As depicted herein, the drain structures 140 are each configured with a third width W3 and the first length L1, and the source structures 142 are each configured with the second length L2 and a fourth width W4 that is different from the third width W3. However, different from the embodiment of FIGS. 6-7B, the third width W3 is greater than the fourth width W4, while the first length L1 and the second length L2 are substantially the same as described above, rendering the drain structure 140 and the source structure 142 to have asymmetric dimensions along the X direction. In this regard, a third area A3 of the bottom surface BS140 is greater than a fourth area A4 of a bottom surface BS142.

FIG. 9 illustrates an example top view of the transistor 105 analogous to the depiction of FIGS. 7A and 7B. The third area A3 is then defined by a product of the third width W3 and the first length L1, and the fourth area A4 is similarly defined by a product of the fourth width W4 and the second length L2, which is less than the third area A3. Accordingly, in contrast to existing device designs in which the third area A3 and the fourth area A4 are configured to be the same, reducing the fourth area A4 relative to the third area A3 effectively reduces source-to-gate capacitance, or C_{gs}, between the source structure 142 and the gate structure 154. A reduced C_{gs} may contribute to improvement in other aspects of the AC performance, such as reduction in loading on the WL structures 155.

In some embodiments, still referring to FIG. 9, the bottom surface BS140 of the drain structure 140 overlaps the top surface TS154 by an overlapping region 146 (depicted to be in the drain structure 140) having a second distance D2, also referred to as an overlapping distance D2, along the X direction. In the depicted embodiment, the overlapping region 146 is symmetrically disposed about the source structure 142 along the X direction. In this regard, an edge 146a of the bottom surface BS140 overlaps an edge 146b of the top surface TS154 by the second distance D2, resulting in the overlapping region 146 to have an overlapping area C1 defined by a product of the second distance D2 and the first length L1, for example. As such, no underlapping configuration is implemented between the drain structure 140 and the gate structure 154.

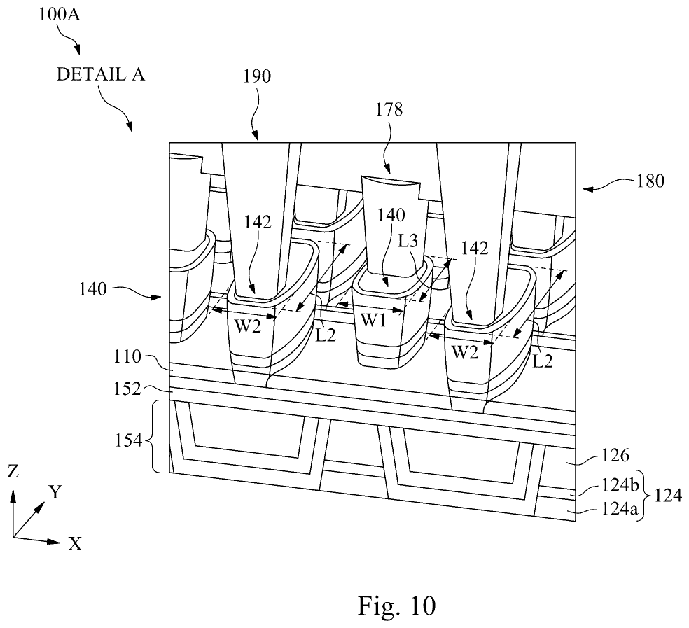

Referring to embodiments of the memory device 100A depicted in FIGS. 10, 11A, and 11B, the drain structure 140 is configured with a third length L3 and the source structure 142 is configured with the second length L2 that is greater than the third length L3, rendering the drain structure 140 and the source structure 142 to have asymmetric dimensions along the Y direction. In this regard, a fifth area A5 of the bottom surface BS140 is less than a sixth area A6 of a bottom surface BS142. In some non-limiting examples, the first width W1 of the drain structure 140 may be the same or substantially the same as the second width W2 of the source structure 142. In some instances, the drain structure 140 with a shortened dimension relative to the source structure 142 may be referred to as a via-type drain structure 140.

In some embodiments, shortening the drain structures 140 may cause the BL structure 180 to overlap the row of the SVIA structures 190 that are electrically coupled to their corresponding source structures and arranged along the X direction. As a result, positions of the BL structure and the nearby row of the SVIAs 190 may be shifted along the Y direction to avoid occurrence of overlapping. In one such example, referring to FIG. 10, the BL structure 180 is positioned behind the row of the SVIAs 190 to accommodate the shortening of the drain structures 140. In contrast, referring to FIG. 4, the BL structure 180 is positioned in front of the row of the SVIAs 190.

FIGS. 11A and 11B each illustrate an example top view of the transistor 105 analogous to the depiction of FIGS. 7A and 7B, respectively. The fifth area A5 is then defined by a product of the first width W1 and the third length L3, and the sixth area A6 is similarly defined by a product of the second width W2 and the second length L2, which is greater than the fifth area A5. Accordingly, in contrast to existing device designs in which the fifth area A5 and the sixth area A6 are configured to be the same, reducing the fifth area A5 relative to the sixth area A6 effectively reduces the C_{gd} between the drain structure 140 and the gate structure 154, which in turn reduces at least the BL loading of the memory device 100A.

In some embodiments, referring to FIG. 11A, the bottom surface BS140 of the drain structure 140 is separated or laterally offset from a top surface TS154 of the gate structure 154 by an underlapping region 147 (defined in the channel layer 110) having the first distance D1 along the X direction. In this regard, an edge 147a of the bottom surface BS140 is separated from an edge 147b of the top surface TS154 by the first distance D1 such that the two surfaces do not overlap but underlap, and an underlapping area B2 of the underlapping region 144 may be defined by a product of the first distance D1 and the third length L3, for example.

In some embodiments, referring to FIG. 11B, the edge 147a of the bottom surface BS140 is vertically aligned with the edge 147b of the top surface TS154 such that the two surfaces do not overlap but underlap. In other words, the edge 147a and the edge 147b coincide with one another. Similar to the difference between the depictions of FIGS. 7A and 7B, the vertical alignment of the bottom surface BS140 and the top surface TS154 indicates an underlapping area that is substantially zero.

In some non-limiting examples, reducing the third length L3 to about 50% of the fourth length L4 decreases the C_{gd} of the memory cell 104, which may lead to a reduction of about 43% in the C_{selector}, a reduction of about 25% in the BL loading, and an improvement in the charge sharing ratio by about 17%. It is noted, however, that if the third length L3 is too short along the Y direction (i.e., if a difference between the third length L3 and the second length L2 is too large), such as greater than about 50%, resistance of the drain structure 140 may be increased too excessively, which may subsequently compromise the DC performance of the memory device 100A. Furthermore, an excessive reduction in the third length L3 relative to the second length L2 may result in poorer gate control of the drain structure 140, which may also compromise the performance of the memory device 100A.

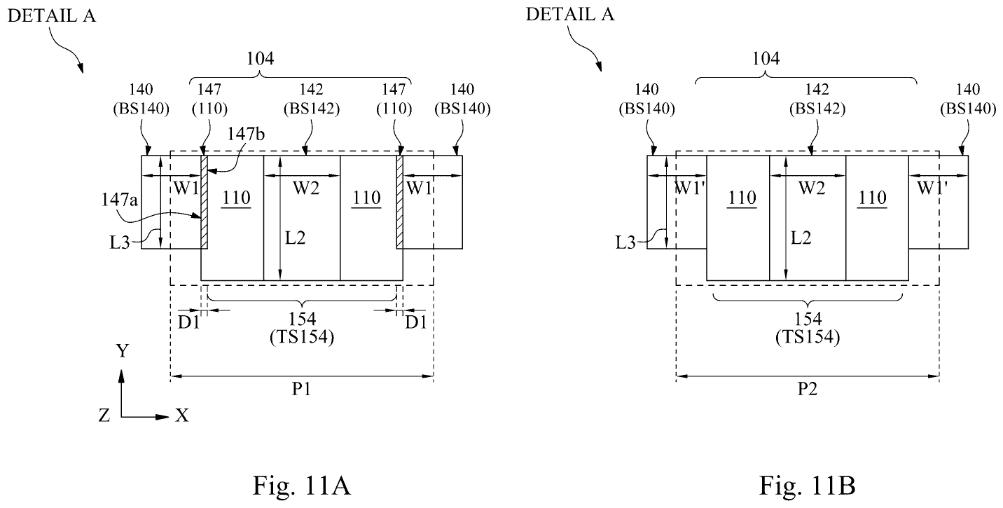

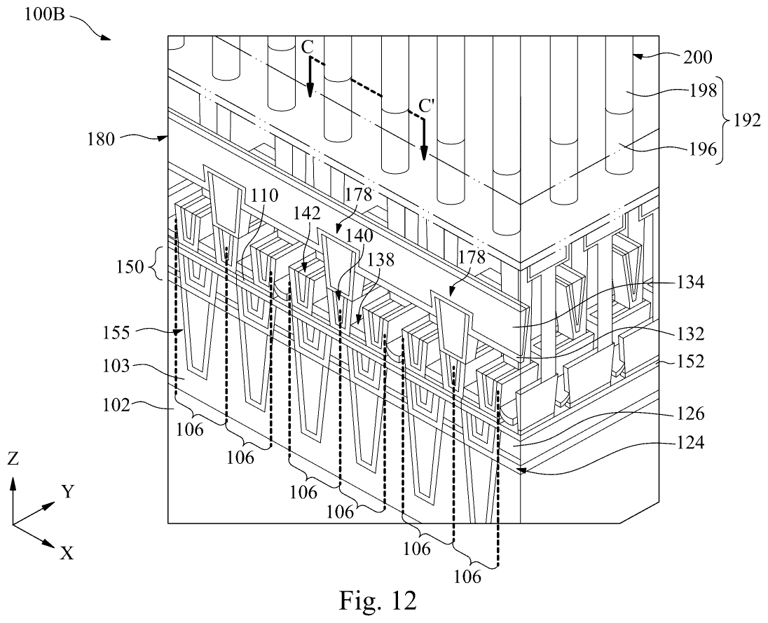

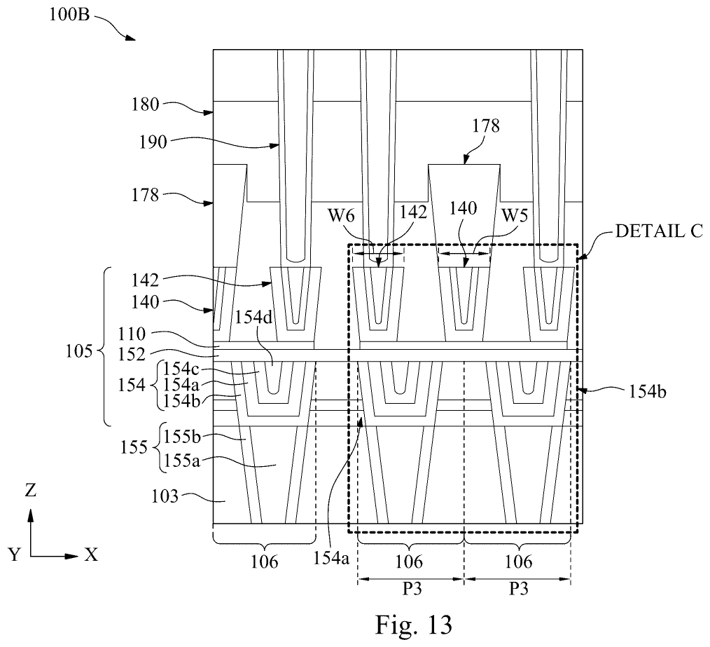

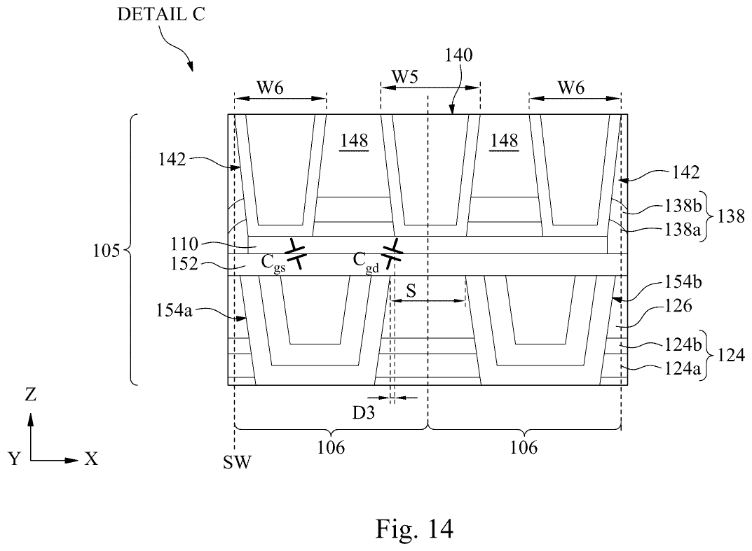

According to various embodiments of the present disclosure, FIG. 12 illustrates a three-dimensional perspective view of a memory device 100B that is similar, though not identical, to the memory device 100A; FIG. 13 illustrates a cross-sectional view of the memory device 100B taken along line CC′ as shown in FIG. 12; and FIG. 14 illustrates a cross-sectional view of a portion the memory device 100B shown as DETAIL C in FIG. 13. Similar to the memory device 100A, the memory device 100B includes a plurality of memory cells 106 arranged as a memory array (e.g., six memory cells 106 are shown in the example of FIG. 12) that extends along both a X direction and the Y direction. It should be understood that the various perspective and cross-sectional views of the memory device 100B described herein are simplified, and thus, it should be understood that any other features/components can also be included in figures pertaining to the memory device 100B, while remaining within the scope of the present disclosure. Each memory cell 106 includes components that are substantially similar to or the same as those of the memory cell 104 described above. As such, these components are referred below using the same numerals as those of the components of the memory cell 104 and their descriptions are not repeated for purposes of brevity.

Similar to the memory cell 104, the memory cell 106 includes at least the transistor 105 electrically coupled to the capacitor 200. The transistor 105 includes the channel layer 110, and the pair of the drain structure 140 and the source structure 142 disposed on the frontside of the channel layer 110, a gate dielectric layer 152 disposed on the backside of the channel layer 110. The transistor 105 further includes the gate structure 154 on the backside of the channel layer 110 and the gate dielectric layer 152 disposed between the gate structure 154 and the channel layer 110. The memory cell 106 further includes the SVIA 190 configured to electrically couple the source structure 142 to the capacitor 200. The memory device 100B further includes a plurality of the WL structures 155 each electrically coupled to the gate structure 154 of each memory cell 106, and the BL structure 180 electrically coupled to each drain structure 140 of the memory cell 106 through the BVIA structure 178.

However, different from the memory cell 104, the drain structure 140 of each memory cell 106 is commonly shared with an adjacent memory cell 106 such that a cell pitch P3 of the memory cell 106 is less than the cell pitch P1 of the memory cell 104 as depicted in at least FIG. 2. In some embodiments, the cell pitch P1 is 1.5 times that of the cell pitch P3, signifying and increase in device density for the memory device 100B in comparison to the memory device 100A. In addition, the arrangement of the drain structures 140 and the source structures 142 in the memory cell 106 also reduces a dimension of each corresponding gate structure 154 along the X direction. Furthermore, the channel layer 110 of the memory device 100B only extends between two adjacent source structures 142 along the X direction, thereby covering only a portion of the gate dielectric layer 152 that engages the gate structures 154 across two adjacent and symmetric memory cells 106.

Referring to FIGS. 12-14, the drain structures 140 are each configured with a fifth width W5 along the X direction and the source structures 142 are each configured with a sixth width W6 along the X direction that is substantially the same as the fifth width W5. Though not depicted herein, the drain structures 140 and the source structures 142 are configured with the same length along the Y direction. In this regard, an area of the bottom surface BS140 of the drain structure 140 facing the channel layer 110 is approximately the same as an area of the bottom surface BS142 of the source structure 142, rendering the drain structure 140 and the source structure 142 to have symmetric dimensions along the X direction and the Y direction, respectively.

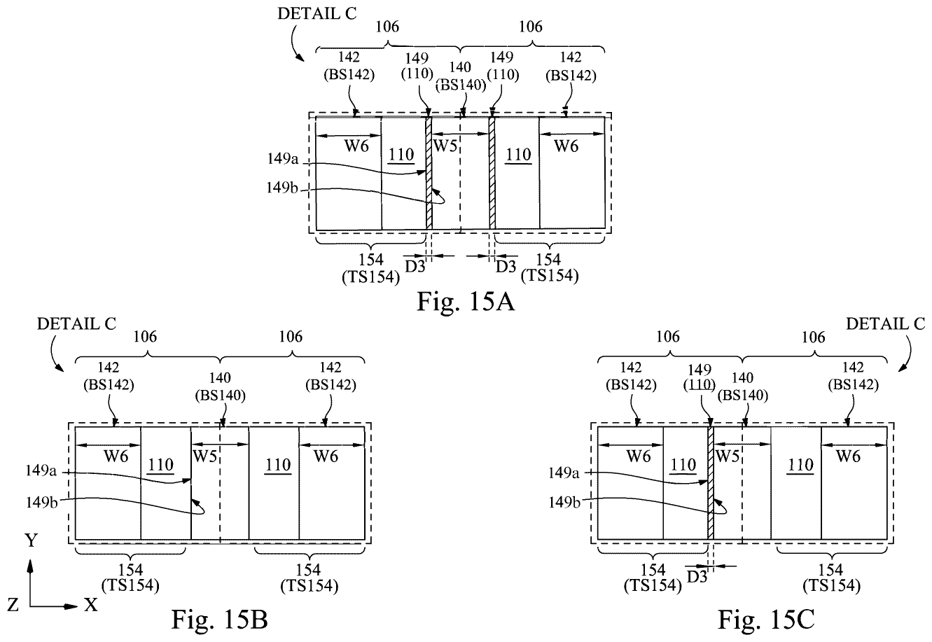

Analogous to the embodiments depicted in FIGS. 2-4, 6, and 7A with respect to the memory device 100A, FIG. 15A illustrates an example top view of the transistor 105 taken along an interface between the drain structure 140 (and the source structure 142) and the channel layer 110 of the portion of the memory device 100B shown as DETAIL C in FIG. 13. The bottom surface BS140 of the drain structure 140 is separated or laterally offset from a top surface TS154 of the gate structure 154 by an underlapping region 149 (defined in the channel layer 110) having a third distance D3 and symmetrically disposed about the drain structure 140 along the X direction. In this regard, an edge 149a of the bottom surface BS140 is separated from an edge 149b of the top surface TS154 by the third distance D3 such that the two surfaces do not overlap but underlap, and an underlapping area B3 of the underlapping region 149 may be defined by a product of the third distance D3 and a length of the drain structure 140 (or the source structure 142), for example.

In some embodiments, referring to FIG. 15B, which is analogous to the embodiments depicted in FIGS. 2-4, 6, and 7B with respect to the memory device 100A, the edge 149a is vertically aligned with the edge 149b such that the two surfaces do not overlap but underlap. In other words, the edge 149a and the edge 149b coincide with one another. In the depicted embodiment, such vertical alignment is present on both sides of and symmetrically about the drain structure 140 along the X direction. Different from the embodiment depicted in FIG. 15A, the vertical alignment of the bottom surface BS140 and the top surface TS154 indicates an underlapping area that is substantially zero. In some embodiments, referring to FIG. 15C, the underlapping region 149 is arranged asymmetrically about the drain structure 140 such that it is only present on a first side of the drain structure 140, the drain structure 140 and the gate structure 154 have vertically aligned edges on a second side of the drain structure 140 opposite to the first side.

Accordingly, referring to FIGS. 15A-15C collectively, for the memory cell 106 having the drain structure 140 and the source structure 142 with symmetric dimensions, underlapping the bottom surface BS140 and the top surface TS154 on one or both sides of the drain structure 140 effectively increases the separation distance between the drain structure 140 and the gate structure 154, thereby reducing the C_{gd} between the drain structure 140 and the gate structure 154 and resulting in improvement in at least the BL loading of the memory device 100B.

In some embodiments, referring to FIG. 14, a distance S between two gate structures 154 (the top surfaces TS154 thereof) of two adjacent memory cells 106 is lengthened along the X direction to increase the separation distance between each of the gate structures 154 and its corresponding drain structure 140. This adjustment may be implemented in addition to implementing the underlapping between the bottom surface BS140 and the top surface TS154 as depicted in FIGS. 15A-15C. In some non-limiting examples, the distance S may be increased from about 13 nm to about 30 nm along the X direction.

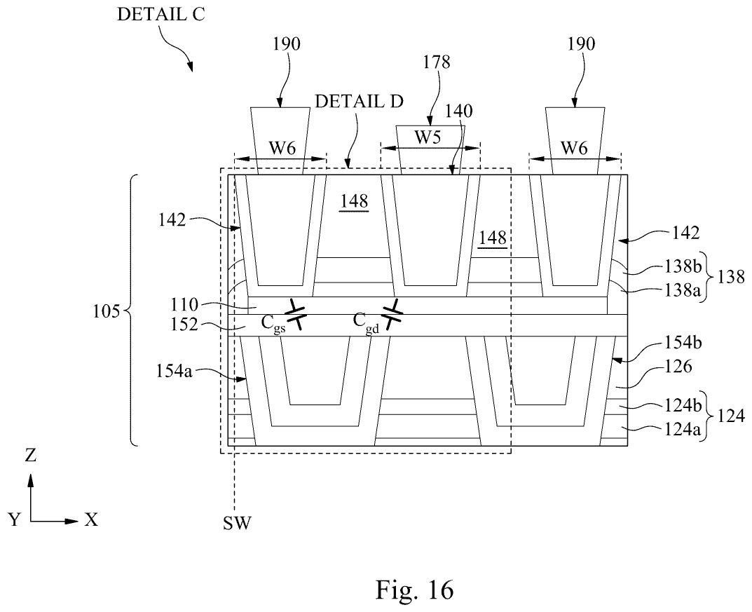

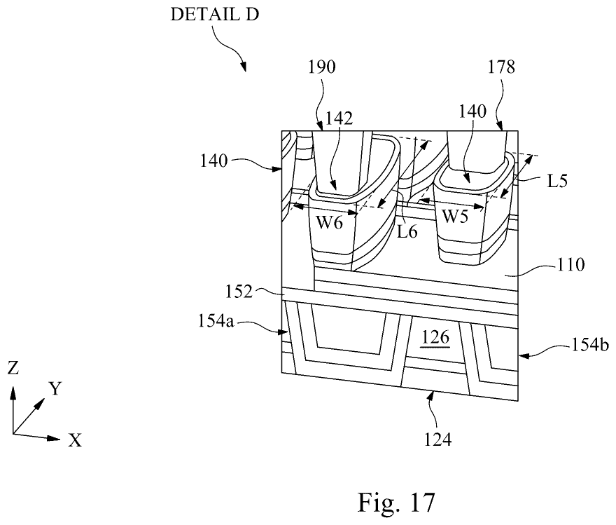

FIG. 16 illustrates a cross-sectional view of the portion the memory device 100B shown as DETAIL C in FIG. 13, and FIG. 17 illustrates a three-dimensional perspective view of a portion of the memory device 100B shown as DETAIL D in FIG. 16. In some embodiments, FIGS. 16 and 17 depict an embodiment of the memory device 100B that is similar to those depicted in FIGS. 12-15C. For example, the drain structures 140 are each configured with the fifth width W5 along the X direction and the source structures 142 are each configured with the sixth width W6 along the X direction that is substantially the same as the fifth width W5. However, different from the embodiment depicted in FIGS. 12-15C, the drain structure 140 is configured with a fifth length L5 and the source structure 142 is configured with a sixth length L6 that is greater than the fifth length L5, rendering the drain structure 140 and the source structure 142 to have asymmetric dimensions along the Y direction. In this regard, a seventh area A7 of the bottom surface BS140 is less than an eighth area A8 of a bottom surface BS142. Accordingly, in contrast to existing device designs in which the seventh area A7 and the eighth area A8 are configured to be the same, reducing the seventh area A7 relative to the eighth area A8 effectively reduces the C_{gd} between the drain structure 140 and the gate structure 154, thereby improving at least the BL loading of the memory device 100B.

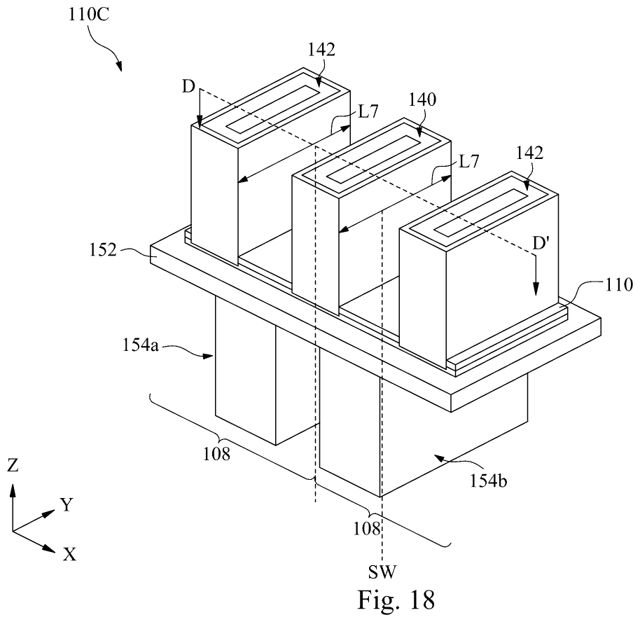

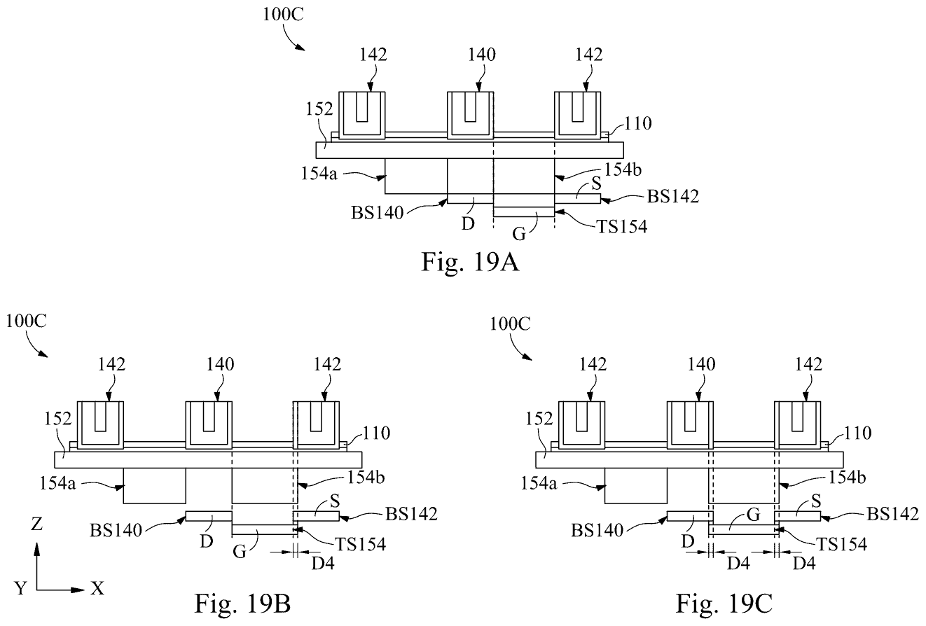

According to various embodiments of the present disclosure, FIG. 18 illustrates a three-dimensional perspective view of a memory device 100C that is similar, though not identical, to the memory device 100B, and FIGS. 19A, 19B, and 19C each illustrate a cross-sectional view of the memory device 100C taken along line EE′ as shown in FIG. 18. Similar to the memory device 100B, the memory device 100C includes a plurality of memory cells 108 arranged as a memory array (e.g., two memory cells 108 are shown in the example of FIG. 18). It should be understood that the various perspective and cross-sectional views of the memory device 100C described herein are simplified, and thus, it should be understood that any other features/components can also be included in figures pertaining to the memory device 100C, while remaining within the scope of the present disclosure. For example, while only two adjacent transistors 105 of the memory cell 108 is illustrated in FIGS. 18-19C, the memory cell 108 also includes additional components not depicted, such as a capacitor electrically coupled to the transistor.

Each memory cell 108 includes components that are substantially similar to or the same as those of the memory cell 106 described above. For example, the drain structure 140 is commonly shared between two adjacent memory cells 108 along the X direction, effectively shortening a cell pitch of the memory cell 108 (e.g., in comparison to the cell pitch P1 of the memory cell 104) and improving the device density as a result. In addition, the arrangement of the drain structures 140 and the source structures 142 in the memory cell 108 also reduces a dimension of each corresponding gate structure 154 along the X direction. However, different from the memory cell 106, each source structure 142 is disposed adjacent to the SW of the gate structure 154 such that a substantially portion of the bottom surface BS142 of the source structure 142 is laterally offset from the top surface TS154 of the gate structure 154 along the X direction. In contrast, referring to FIG. 14, for example, one of the sidewalls of the source structure 142 is aligned, or substantially aligned with the SW of the gate structure 154 and the top surface TS154 overlaps an entirety of the bottom surface BS142. Features with designations “D,” “G,” and “S” are schematic projections of the drain structure 140, the gate structure 154, and the source structure 142, respectively, for illustrating relative positions of these components along the X direction.

In some embodiments, referring to FIG. 19A, the top surface TS154 underlaps each of the bottom surface BS140 of the drain structure 140 and the bottom surface BS142 in the memory cell 108. In some embodiments, referring to FIG. 19B, the top surface TS154 underlaps the bottom surface BS140 and overlaps the bottom surface BS142, where an overlapping region may be defined by a fourth distance D4. In some non-limiting examples, the fourth distance D4, also referred to as the overlapping distance D4, may be greater than 0 and less than or equal to about 2 nm. In some embodiments, referring to FIG. 19C, the top surface TS154 overlaps each of the bottom surface BS140 and the bottom surface BS142, where each overlapping region may be defined by the fourth distance D4.

In the depicted embodiments of FIGS. 19A-19C, “underlapping” between two surfaces refers to the two surfaces being separated by a distance (e.g., the fourth distance D4), similar to the embodiments depicted in FIGS. 15A and 15C, or alternatively, having edges vertically aligned or coincide with one another, as depicted in FIGS. 19A and 19B and similar to the embodiment depicted in FIG. 15B. In various embodiments of the present disclosure, underlapping between the gate structure 154 and the drain structure 140 improves the AC performance of the memory device 100A/100B/100C by reducing the C_{gd} as described herein, while overlapping between the gate structure 154 and the source structure 142 allows or maintains adequate DC performance (e.g., a sufficient on-current Iₒₙ) of the memory device 100A/100B/100C.

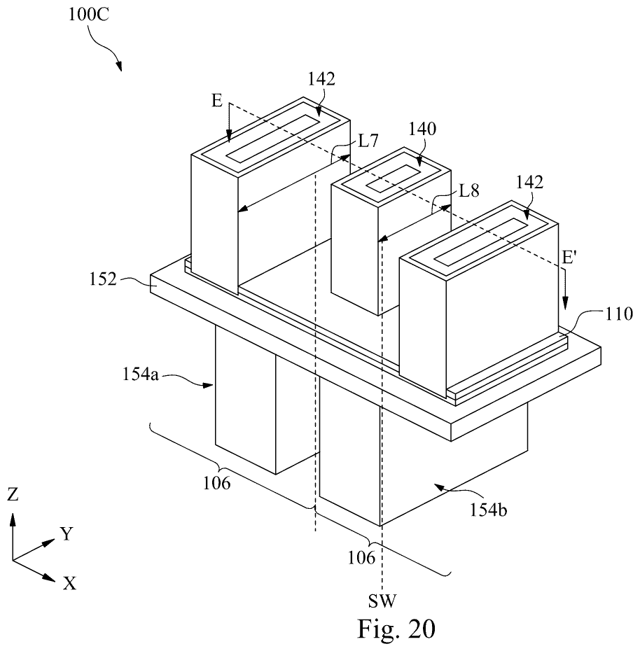

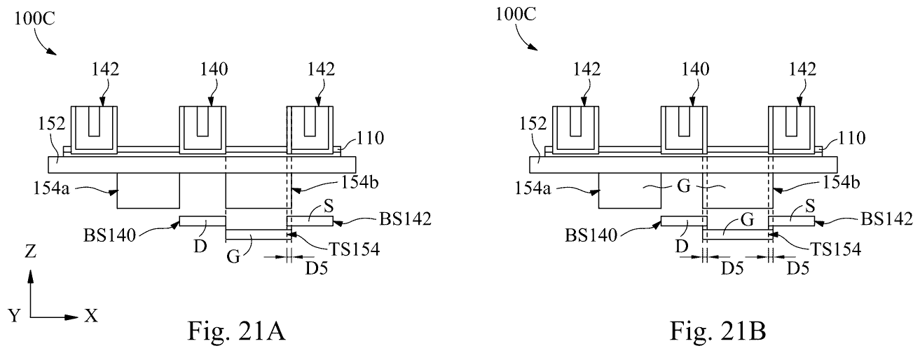

In some embodiments, referring to FIGS. 18-19C collectively, the drain structure 140 and the source structure 142 have the same dimension, a seventh length L7, along the Y direction. In some embodiments, however, referring to FIGS. 20, 21A, and 21B collectively, the drain structure 40 has a dimension, an eighth length L8, shorter than the seventh length L7 of the source structure 142. In this regard, an area of the bottom surface BS140 is less than an area of the bottom surface BS142, effectively reducing the C_{gd} between the drain structure 140 and the gate structure 154, which in turn reduces at least the BL loading of the memory device 100C.

According to various embodiments of the present disclosure, FIG. 20 illustrates a three-dimensional perspective view of the memory device 100C, and the FIGS. 21A and 21B each illustrate a cross-sectional view of a portion of the memory device 100C taken along line EE′ as shown in FIG. 20. Similar to FIGS. 19A-19C, features with designations D,” “G,” and “S” are schematic projections of the drain structure 140, the gate structure 154, and the source structure 142, respectively, for illustrating relative positions of these components along the X direction. In some embodiments, referring to FIG. 21A, the top surface TS154 underlaps the bottom surface BS140 and overlaps the bottom surface BS142, where an overlapping region may be defined by a fifth distance D5, also referred to as an overlapping distance D5. As described above, the overlapping distance D5 may be greater than 0 and less than or equal to about 2 nm in some non-limiting examples. In some embodiments, referring to FIG. 21B, the top surface TS154 overlaps each of the bottom surface BS140 and the bottom surface BS142, where each overlapping region may be defined by the fifth distance D5. Due to the reduced area of the bottom surface BS140, overlapping between the gate structure 154 and the source structure 142 maintains or enhances the DC performance of the memory device 100C.

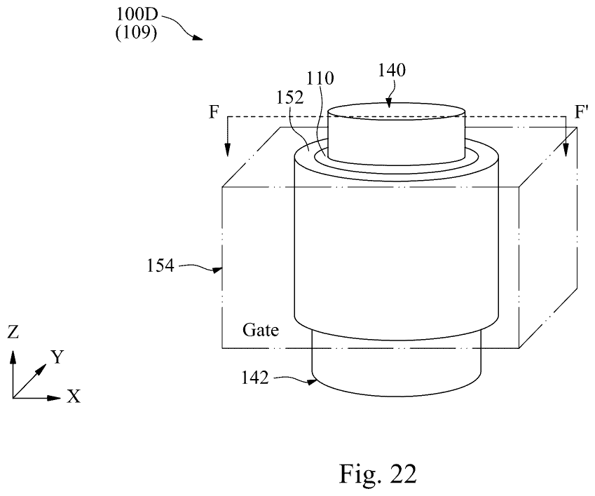

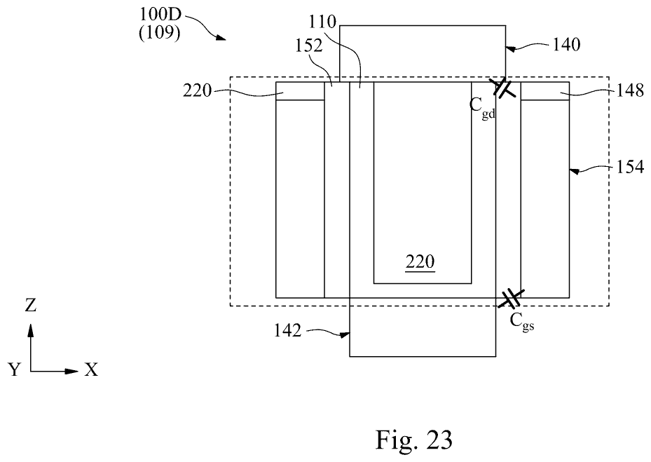

According to various embodiments of the present disclosure, FIG. 22 illustrates a three-dimensional perspective view of a memory device 100D and FIG. 23 illustrates a cross-sectional view of the memory device 100D taken along line FF′ as shown in FIG. 22. Specifically, a memory cell 109 of the memory device 100D is depicted in each of the FIGS. 22 and 23. Different from the embodiments of the memory cells 104, 106, and 108, the drain structure 140 and the source structure 142 of the memory cell 109 are disposed along the Z direction and separated by the gate structure 154, which has a tubular shape that extends lengthwise along the Z direction. The memory device 100D includes a dielectric layer 220 disposed within and surrounded circumferentially by the gate structure 154, where the dielectric layer 220 may be similar to or the same as the dielectric layer 103 in composition. The memory cell 109 also includes the channel layer 110 and the gate dielectric layer 152 over the channel layer 110, where the channel layer 110 and the gate dielectric layer 152 are disposed between the gate structure 154 and the dielectric layer 220. In this regard, by configuring the channel layer 110 and the gate structure 154 to extend along the Z direction and the drain structure 140 to extend along the X direction, a separation distance between the drain structure 140 and the gate structure 154 is increased, which results in a reduction of the C_{gd} as described in detail above.

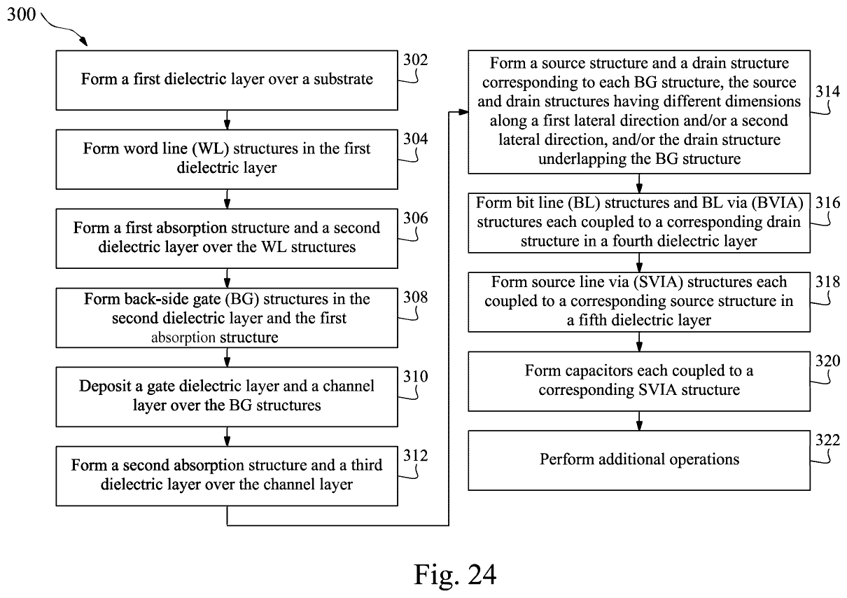

FIG. 24 illustrates a flowchart of a method 300 for forming a memory device according to various embodiments of the present disclosure. For example, at least some of the operations (or steps) of the method 300 can be performed to fabricate, make, or otherwise form a memory device (e.g., any of the memory devices 100A, 100B, or 100C, etc.). The method 300 is merely an example, and is not intended to limit the present disclosure. Accordingly, it should be understood that additional operations may be provided before, during, and after the method 300 of FIG. 24, and that some other operations may only be briefly described herein.

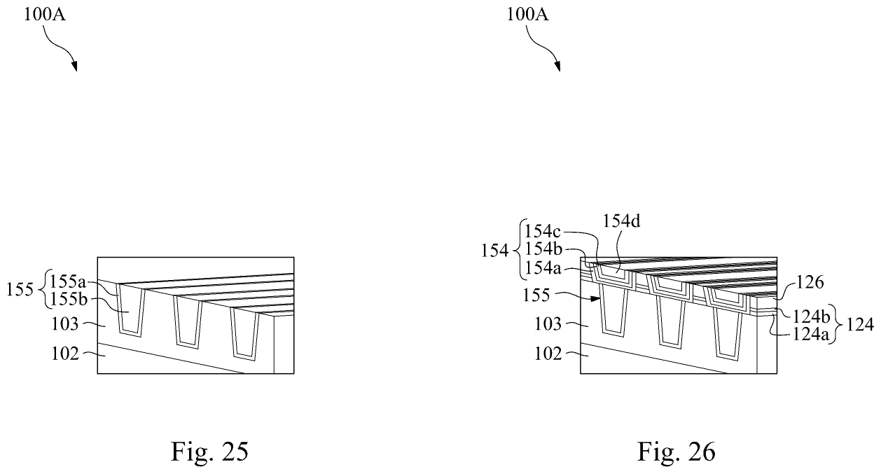

The operations of the method 300 are described below in the context of forming an embodiment of the memory device 100A depicted in one or more of FIGS. 1-11B for illustrative purposes only. However, it should be understood that the operations of the method 300 may also be employed to form embodiments of the memory device 100B or 100C as described herein. In various embodiments, operations of the method 300 are associated with three-dimensional perspective views of a portion of the memory device 100A at various fabrication stages as shown in FIGS. 25, 26, 27, 28, 29, 30, 31, and 32.

Referring to FIGS. 24 and 25, the dielectric layer 103 is formed over the base structure 102 at operation 302. In the present embodiments, the dielectric layer 103 is formed as a blanket layer over an entirety of the base structure 102 and thus extends along both the X direction and the Y direction. In some embodiments, the base structure 102 may be provided or formed by performing a series of IC fabrication operations, such as lithography, etching, deposition, etc., resulting in various FEOL, MEOL, and BEOL network/processing components over and/or in the frontside of the major surface of the semiconductor substrate described herein. In the present embodiments, the dielectric layer 103 is formed as a part of the BEOL network/processing components, such as the dielectric layer for the M5 metallization layer. The dielectric layer 103 may be formed over the base structure by any suitable deposition method, such as chemical vapor deposition (CVD), flowable CVD (FCVD), spin-on coating, other suitable methods, or combinations thereof.

Still referring to FIGS. 24 and 25, the plurality of the WL structure 155 are formed in the dielectric layer 103 at operation 304. In the present embodiments, the WL structures 155 are formed in the dielectric layer 103 by first performing a patterning process to form trenches (not depicted) in the dielectric layer 103, where the trenches extend lengthwise along the Y direction and separated from each other along the X direction. In some embodiments, the WL structures 155 are each embedded in and surrounded by the dielectric layer 103. In some embodiments, the WL structure 155 do not extend through the dielectric layer 103.

In some embodiments, performing the patterning process includes depositing a masking layer (e.g., a photoresist) over the dielectric layer 103, patterning the masking layer using a suitable lithography process (e.g., photolithography, e-beam lithography, or any other suitable lithographic process) to form a patterned masking layer, and subsequently performing a series of etching processes to transfer the pattern on the patterned masking layer to the dielectric layer, thereby forming the trenches. The etching process may include a plasma etching process, which can have a certain amount of anisotropic characteristic, a wet etching process, a reactive ion etching (RIE) process, other suitable processes, or combinations thereof. In other embodiments, a hard mask may first be patterned using the masking layer and the pattern be subsequently transferred to the dielectric layer 103. After forming the trenches, the patterned masking layer is removed by a suitable method, such as plasma ashing or resist stripping.

Subsequently, the barrier layer 155a is conformally deposited in the trenches, and the fill layer 155b is then deposited over the barrier layer 155a to fill the trenches. The barrier layer 155a and the fill layer 155b are each deposited by any suitable deposition process, such as CVD, atomic layer deposition (ALD), physical vapor deposition (PVD), plating (e.g., electroplating, electroless plating, etc.), other suitable methods, or combinations thereof. Thereafter, the barrier layer 155a and the fill layer 155b are planarized by a chemical-mechanical planarization/polishing (CMP) process, for example, resulting in a substantially planar surface across top surfaces of the dielectric layer 103 and the WL structures 155.

Referring to FIGS. 24 and 26, the absorption structure 124 and the dielectric layer 126 are formed over the WL structures 155 at operation 306. The material layers of the absorption structure 124, including the dielectric layer 124a and the absorption layer 124b, are sequentially deposited as blanket layers by any suitable deposition process, such as CVD, ALD, PVD, flowable CVD, other suitable methods, or combinations thereof. Subsequently, the dielectric layer 126 is deposited as a blanket layer over the absorption structure 124 by any suitable method similar to the methods described above with respect to forming the dielectric layer 103.

Still referring to FIGS. 24 and 26, the gate structures 154 are formed in the dielectric layer 126 and the absorption structure 124 at operation 308. Trenches (not depicted) are first formed in the dielectric layer 126 and the absorption structure 124 by a series of photolithography and etching processes similar to those described above with respect to forming the trenches for the WL structure 155. The trenches extend lengthwise along the Y direction and separated from each other along the X direction. Each of the trenches is vertically aligned with a corresponding one of the WL structure 155 along the Z direction. In the present embodiments, each of the trenches extends vertically through the dielectric layer 126 and the absorption structure 124 such that it exposes a top surface of the corresponding WL structure 155.

Subsequently, various material layers of the gate structure 154, including the material layers 154a, 154b, 154c, and 154d, are sequentially deposited in the trenches by any suitable deposition process described above with respect to the barrier layer 155a and the fill layer 155b. In some embodiments, one or more of the material layers 154a-154d are omitted from the gate structure 154. Thereafter, the various material layers are planarized using one or more CMP processes to form the gate structures 154.

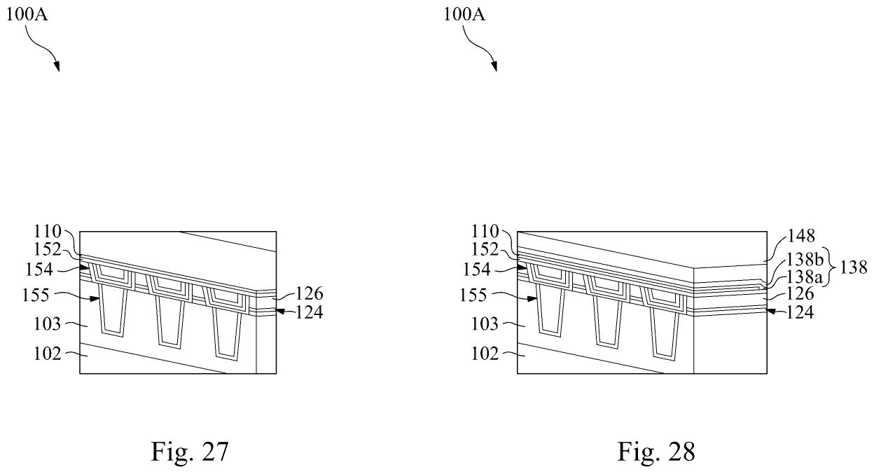

Referring to FIGS. 24 and 27, the gate dielectric layer 152 and the channel layer 110 are deposited over the gate structures 154 at operation 310. In some embodiments, the gate dielectric layer 152 and the channel layer 110 are each formed as a blanket layer over the gate structures 154 and the dielectric layer 126 using any suitable deposition process similar to those described above with respect to the barrier layer 155a and the fill layer 155b.

In some embodiments, the channel layer 110 is subsequently patterned to expose some portions of the underlying gate dielectric layer 152. In one such example, referring to FIGS. 1-4, the channel layer 110 may be patterned to form regions that are separated along the Y direction by portions of the gate dielectric layer 152. In this regard, each region of the channel layer 110 extends lengthwise along the X direction. In another such example, referring to FIGS. 12-14, the channel layer 110 may be patterned to form regions that are separated along both the X direction and the Y direction by portions of the gate dielectric layer 152. The channel layer 110 may be patterned using a series of photolithography and etching processes similar to those described above with respect to forming the trenches for the WL structure 155.

Referring to FIGS. 24 and 28, the absorption structure 138 and the dielectric layer 148 are formed over the channel layer 110 at operation 312. The material layers of the absorption structure 138, including the dielectric layer 138a and the absorption layer 138b, are sequentially deposited as blanket layers by any suitable deposition process similar to those described above with respect to forming the absorption structure 124. Subsequently, the dielectric layer 148 is deposited over the absorption structure 124 by any suitable method similar to the method described above with respect to forming the dielectric layer 103.

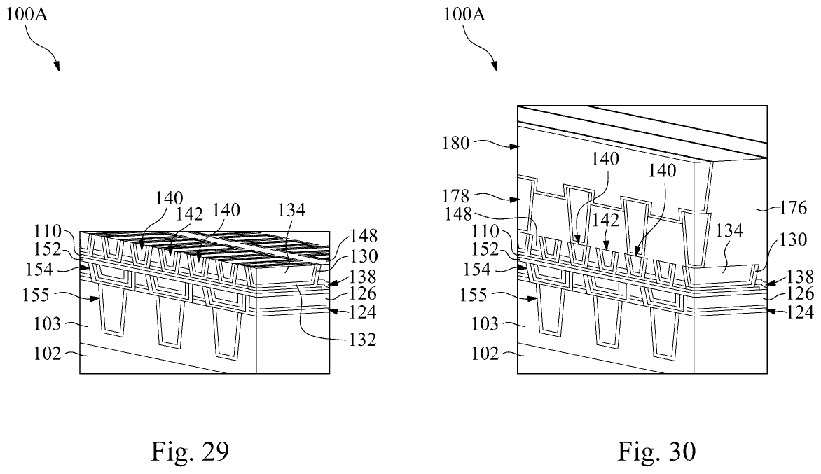

Referring to FIGS. 24 and 29, a pair of the drain structure 140 and the source structure 142 are formed in the dielectric layer 148 corresponding to each gate structure 154 at operation 314. In some embodiments, referring to FIGS. 1-4 and 6-11B, the drain structure 140 and the source structure 142 in each memory cell 104 are formed to have different widths along the X direction or different lengths along the Y direction. Alternatively or additionally, referring to FIGS. 1-4, 6-7B, and 10-11B, the bottom surface BS140 of the drain structure 140 in each memory cell 104 is formed to underlap the top surface TS154 of the gate structure 154 in the same memory cell 104. Furthermore, referring to FIGS. 6 and 8, for example, each source structure 142 may be formed such that its centerline is aligned, or substantially aligned, with a centerline CL of the gate structure 154 underlying the source structure 142.

To form the drain structures 140 and the source structures 142, trenches (not depicted) are first formed in the dielectric layer 148 and the absorption structure 138 by a series of photolithography and etching processes similar to those described above with respect to forming the trenches for the WL structure 155. The trenches extend lengthwise along the Y direction and separated from each other along the X direction. Dimensions of the trenches and their relative positions with respect the gate structure 154 are configured according to various embodiments described herein with respect to the memory devices 100A, 100B, and 100C.

Subsequently, various material layers of each of the drain structure 140 and the source structure 142, including the absorption layer 130, the metal layer 132, and the metal layer 134, are sequentially deposited in the trenches by any suitable deposition process described above with respect to the barrier layer 155a and the fill layer 155b. In some embodiments, one or more of the absorption layer 130, the metal layer 132, and the metal layer 134 are omitted from each of the drain structures 140 and the source structures 142. Thereafter, the various material layers are planarized using one or more CMP processes to form the drain structures 140 and the source structures 142 in the dielectric layer 148.

In some embodiments, such as those depicted with respect to the memory device 100B, each source structure 142 may be formed such that one of its sidewalls is aligned, or substantially aligned, with the sidewall SW of the gate structure 154 and an entirety of the bottom surface BS142 may overlap or traverse the top surface TS154 along the X direction. In some embodiments, such as those depicted with respect to the memory device 100C, the source structure 142 is disposed adjacent to the sidewall SW of the gate structure 154 and a substantially portion of the bottom surface BS142 of the source structure 142 is laterally offset from and non-overlapping the top surface TS154 along the X direction.

Referring to FIGS. 24 and 30, the BVIA structures 178 and the BL structure 180 are formed in the dielectric layer 176 at operation 316. In some embodiments, a first portion of the dielectric layer 176 is first deposited over the drain structures 140 and the source structures 142 as a blanket layer by any suitable method similar to those described above with respect to forming the dielectric layer 103. Trenches (not depicted) are then formed in the first portion of the dielectric layer 176 by a series of photolithography and etching processes similar to those described above with respect to forming the trenches for the WL structure 155. The trenches are separated from each other along the X direction and are each vertically aligned with a corresponding one of the drain structures 140 along the Z direction. In the present embodiments, each of the trenches extends vertically through the first portion of the dielectric layer 176 such that it exposes a top surface of the corresponding drain structure 140.

Subsequently, various material layers of the BVIA structures 178, including the metal layer 132 and the metal layer 134, are sequentially deposited in the trenches by any suitable deposition process described above with respect to the barrier layer 155a and the fill layer 155b. Thereafter, the various material layers are planarized using one or more CMP processes to form the BVIA structures 178.

Thereafter, a second portion of the dielectric layer 176 is deposited as a blanket layer over the BVIA structures 178 and the first portion of the dielectric layer 176 by any suitable method similar to those described above with respect to forming the dielectric layer 103. A trench is then formed in the second portion of the dielectric layer 176 by a series of photolithography and etching processes similar to those described above with respect to forming the trenches for the WL structure 155. The trench extends lengthwise along the X direction to expose a top surface of each BVIA structure 178. In some embodiments, the trench also exposes a portion of each sidewall of the BVIA structure 178 such that a top portion of each BVIA structure 178 extends into the trench.

Subsequently, various material layers of the BL structure 180, including the metal layer 132 and the metal layer 134, are sequentially deposited in the trench by any suitable deposition process described above with respect to the barrier layer 155a and the fill layer 155b. Thereafter, the various material layers are planarized using one or more CMP processes to form the BL structure 180. In some embodiments, the top portion of each BVIA structure 178 extends into and is embedded in the BL structure 180. The resulting BVIA structures 178 each electrically couple a corresponding drain structure 140 to the BL structure 180.

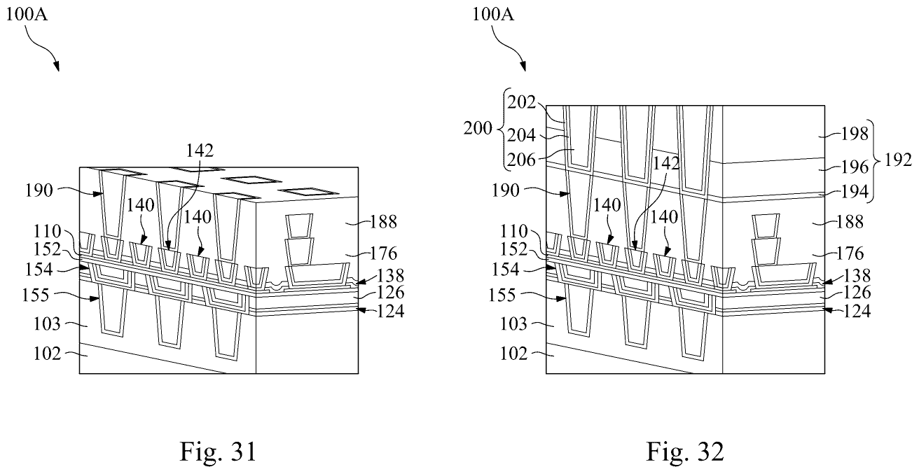

Referring to FIGS. 24 and 31, the SVIA structures 190 are formed in the dielectric layer 188 at operation 318. The SVIA structures 190 may be formed in a manner similar to that of forming the BVIA structures 178. For example, the dielectric layer 188 is first deposited over the BL structure 180 and the dielectric layer 176 as a blanket layer by any suitable method similar to those described above with respect to forming the dielectric layer 103. Trenches (not depicted) are then formed in the dielectric layer 176 and the dielectric layer 188 by a series of photolithography and etching processes similar to those described above with respect to forming the trenches for the WL structure 155. The trenches are separated from each other along the X direction and are each vertically aligned with a corresponding one of the source structures 142 along the Z direction. In the present embodiments, each of the trenches extends vertically through the dielectric layer 176 and the dielectric layer 188 such that it exposes a top surface of the corresponding source structure 142.

Subsequently, various material layers of the SVIA structures 190, including the metal layer 132 and the metal layer 134, are sequentially deposited in the trenches by any suitable deposition process described above with respect to the barrier layer 155a and the fill layer 155b. Thereafter, the various material layers are planarized using one or more CMP processes to form the SVIA structures 190. The resulting SVIA structures 190 are each electrically coupled to the corresponding source structure 142.

Referring to FIGS. 24 and 32, the capacitors 200 are formed in the dielectric structure 192 at operation 320. Various material layers of the dielectric structure 192, including the absorption layer 194, the dielectric layer 196, and the dielectric layer 198, are each deposited as a blanket layer over the SVIA structures 190 and the dielectric layer 188 by any suitable method similar to those described above with respect to forming the dielectric layer 103. Trenches (not depicted) are then formed in the dielectric structure 192 by a series of photolithography and etching processes similar to those described above with respect to forming the trenches for the WL structure 155. The trenches are separated from each other along the X direction and are each vertically aligned with a corresponding one of the SVIA structures 190 along the Z direction. In the present embodiments, each of the trenches extends vertically through the dielectric structure 192 such that it exposes a top surface of the corresponding SVIA structure 190.

Subsequently, various material layers of the capacitors 200, including the bottom plate 202, the capacitor dielectric layer 204, and the top plate 206, are sequentially deposited in the trenches by any suitable deposition process described above with respect to the barrier layer 155a and the fill layer 155b. Thereafter, the various material layers are planarized using one or more CMP processes to form the capacitors 200. The resulting capacitors 200 are electrically coupled to the corresponding source structure 142 through a SVIA structure 190.

Thereafter, additional operations may be performed at operation 322. For example, additional interconnect features, such as vias and conductive lines, may be formed over the memory device 100A according to various design requirements.

In one aspect of the present disclosure, a memory device is disclosed. The memory device includes a channel layer. The memory device includes a gate structure on a first side of the channel layer, where the gate structure has a top surface facing the channel layer. The memory device includes a drain structure on a second side of the channel layer opposite to the first side, where the drain structure has a first bottom surface in contact with the channel layer. The first bottom surface underlaps the top surface of the gate structure across a lateral direction. The memory device includes a source structure on the second side of the channel layer and adjacent to the drain structure along the lateral direction, where the source structure has a second bottom surface facing the channel layer. The second bottom surface overlaps the top surface of the gate structure across the lateral direction.

In another aspect of the present disclosure, a memory device is disclosed. The memory device includes a channel layer. The memory device includes a gate structure on a backside of the channel layer, where the gate structure has a top surface facing the channel layer. The memory device includes a drain structure on a frontside of the channel layer opposite to the backside, where the drain structure has a first bottom surface facing the channel layer. The first bottom surface non-overlaps the top surface along a lateral direction and has a first width along the lateral direction. The memory device includes a source structure on the frontside of the channel layer and adjacent to the drain structure, where the source structure has a second bottom surface facing the channel layer. The second bottom surface overlaps the top surface along the lateral direction. The second bottom surface has a second width along the lateral direction that is different from the first width.

In yet another aspect of the present disclosure, a method for fabricating a memory devices is disclosed. The method includes forming a first dielectric layer over a base structure. The method includes forming a word line structure in the first dielectric layer. The method includes forming a second dielectric layer over the word line structure. The method includes forming a back-side gate structure in the second dielectric layer, where the back-side gate structure extends along a first lateral direction. The method includes forming a high-k gate dielectric layer over the back-side gate structure. The method includes forming a semiconductor layer over the high-k gate dielectric layer. The method includes forming a source structure and a drain structure adjacent to the source structure along a second lateral direction perpendicular to the first lateral direction in a top view of the memory cell, where the drain structure has a first bottom surface facing the semiconductor layer and the source structure has a second bottom surface facing the semiconductor layer. The first bottom surface differs from the second bottom surface in area across the first lateral direction and the second lateral direction.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a channel layer;
a gate structure on a first side of the channel layer, the gate structure having a top surface facing the channel layer;
a drain structure on a second side of the channel layer opposite to the first side, the drain structure having a first bottom surface in contact with the channel layer, and the first bottom surface underlapping the top surface of the gate structure across a lateral direction; and
a source structure on the second side of the channel layer and adjacent to the drain structure along the lateral direction, the source structure having a second bottom surface facing the channel layer, and the second bottom surface overlapping the top surface of the gate structure across the lateral direction.

2. The memory device of claim 1, wherein a first edge of the top surface of the gate structure is separated from a second edge of the second bottom surface along the lateral direction.

3. The memory device of claim 1, wherein a first edge of the top surface of the gate structure is vertically aligned with a first edge of the first bottom surface.

4. The memory device of claim 1, wherein:
the drain structure has a first width along the lateral direction and the source structure has a second width along the lateral direction, and
the first width is different from the second width.

5. The memory device of claim 1, wherein:
wherein the lateral direction is a first lateral direction,
the drain structure has a first length along a second lateral direction perpendicular to the first lateral direction in a top view of the memory device,
the source structure has a second length along the second lateral direction, and
the first length is less than the second length.

6. The memory device of claim 1, further comprising:
a word line structure electrically coupled to the gate structure;
a bit line structure electrically coupled to the drain structure; and
a capacitor electrically coupled to the source structure.

7. The memory device of claim 1, wherein a sidewall of the gate structure is aligned with a sidewall of the source structure along a vertical direction perpendicular to the lateral direction in a cross-sectional view of the memory device.

8. The memory device of claim 1, wherein a centerline of the gate structure is aligned with a centerline of the source structure along a vertical direction perpendicular to the lateral direction in a cross-sectional view of the memory device.

9. A memory device, comprising:
a channel layer;
a gate structure on a backside of the channel layer, the gate structure having a top surface facing the channel layer;
a drain structure on a frontside of the channel layer opposite to the backside, the drain structure having a first bottom surface facing the channel layer, the first bottom surface non-overlapping the top surface along a lateral direction, and the first bottom surface having a first width along the lateral direction; and
a source structure on the frontside of the channel layer and adjacent to the drain structure, the source structure having a second bottom surface facing the channel layer, the second bottom surface overlapping the top surface along the lateral direction, and the second bottom surface having a second width along the lateral direction that is different from the first width.

10. The memory device of claim 9, wherein the first width is less than the second width.

11. The memory device of claim 9, further comprising:
a bit line structure extending along the lateral direction,
a first via structure electrically coupling the drain structure to the bit line structure,
a capacitor extending along a vertical direction perpendicular to the lateral direction in a cross-sectional view of the memory device, and
a second via structure electrically coupling the source structure to the capacitor.

12. The memory device of claim 9, wherein a sidewall of the source structure is aligned with a sidewall of the gate structure along a vertical direction perpendicular to the lateral direction in a cross-sectional view of the memory device.

13. The memory device of claim 9, further comprising a word line structure coupled to the gate structure, wherein the word line structure is aligned with the gate structure along a vertical direction perpendicular to the lateral direction in a cross-sectional view of the memory device.

14. The memory device of claim 9, wherein:
the lateral direction is a first lateral direction,
the drain structure has a first length along a second lateral direction perpendicular to the first lateral direction in a top view of the memory device,
the source structure has a second length along the second lateral direction, and
the first length is less than the second length.

15. The memory device of claim 9, further comprising:
a first absorption structure on the frontside of the channel layer and interposed between the drain structure and the source structure, and
a second absorption structure on the backside of the channel layer and adjacent to the gate structure, wherein the first absorption structure and the second absorption structure each include a hydrogen absorption layer.

16. A method of fabricating a memory cell, comprising:
forming a first dielectric layer over a base structure;
forming a word line structure in the first dielectric layer;
forming a second dielectric layer over the word line structure;
forming a back-side gate structure in the second dielectric layer, the back-side gate structure extending along a first lateral direction;
forming a high-k gate dielectric layer over the back-side gate structure;
forming a semiconductor layer over the high-k gate dielectric layer; and
forming a source structure and a drain structure adjacent to the source structure along a second lateral direction perpendicular to the first lateral direction in a top view of the memory cell, the drain structure having a first bottom surface facing the semiconductor layer and the source structure having a second bottom surface facing the semiconductor layer, wherein the first bottom surface differs from the second bottom surface in area across the first lateral direction and the second lateral direction.

17. The method of claim 16, wherein the back-side gate structure has a top surface facing the semiconductor layer, and wherein the top surface of the back-side gate structure underlaps the first bottom surface.

18. The method of claim 17, wherein a first edge of the top surface of the back-side gate structure is separated from a second edge of the second bottom surface along the first lateral direction.

19. The method of claim 17, wherein a first edge of the top surface of the back-side gate structure is vertically aligned with a first edge of the first bottom surface.

20. The method of claim 16, further comprising:
forming a first hydrogen absorption layer between the first dielectric layer and the second dielectric layer; and
forming a second hydrogen absorption layer over the semiconductor layer.
